(19) United States
(12) Patent Application Publication
(10) Pub. No.: US 2025/0280574 A1
(43) Pub. Date: Sep. 4, 2025

(54) ELECTRONIC DEVICE INCLUDING A BURIED SHIELD AND A GAP REGION

(71) Applicant: SEMICONDUCTOR COMPONENTS INDUSTRIES, LLC, Scottsdale, AZ (US)

(72) Inventors: Gary Horst LOECHELT, Tempe, AZ (US); Tanuj SAXENA, Chandler, AZ (US)

(73) Assignee: SEMICONDUCTOR COMPONENTS INDUSTRIES, LLC, Scottsdale, AZ (US)

(21) Appl. No.: 19/055,924

(22) Filed: Feb. 18, 2025

Related U.S. Application Data
(60) Provisional application No. 63/560,310, filed on Mar. 1, 2024.

(51) Int. Cl. H10D 62/10; H10D 30/01; H10D 30/66; H10D 62/00; H10D 62/832

(52) U.S. Cl. CPC H10D 62/109; H10D 30/0297; H10D 30/668; H10D 62/054; H10D 62/8325

(57) ABSTRACT

An electronic device can include a buried shield and at least one gap region. In an implementation, a source region can include shallow and deep portions. A centerline through the gap region may pass through the shallow portion and not the deep portion. In the same or different implementation, the shallow portion can overlap the gap region, and the deep portion does not overlap the gap region. The electronic device can be designed to have a good balance between source contact resistance and BV_{DS}. In a further implementation, the electronic device can include first and second gap regions. Lengths of the first and second gap regions can lie long lines that interest each other. The gap regions can be designed so that a gap region resistance may be within an order of magnitude of a channel resistance corresponding to channel regions of transistor structures within a power transistor.

### CROSS REFERENCE TO RELATED APPLICATION

This application claims priority under 35 U.S.C. § 119 (e) to U.S. Patent Application No. 63/560,310 entitled “Electronic Device Including a Power Transistor,” by Loechelt et al., filed Mar. 1, 2024, which is assigned to the current assignee hereof and incorporated herein by reference in its entirety.

### FIELD OF THE DISCLOSURE

The present disclosure relates to an electronic device, and more particularly, to an electronic device that includes a buried shield and a gap region.

### RELATED ART

Transistors can be designed to operate at relatively high voltages and high currents. Some semiconductor materials, such as monocrystalline Si, may not be able to operate at such high voltages and currents or may need complex designs to withstand the high voltages and current during operation. Wide band gap semiconductors such as SiC can be used in transistors that operate at high voltages and current. The power transistor can have a relatively high electrical field in regions near a primary surface of a substrate. Scaling transistors to smaller dimensions while maintaining an acceptable drain-to-source punchthrough voltage can be challenging. Further improvement for the power transistor is desired.

### BRIEF DESCRIPTION OF THE DRAWINGS

Implementations are illustrated by way of example and are not limited in the accompanying figures.

FIG. 1 includes an illustration of a cross-sectional view of a portion of a workpiece that includes a substrate that includes a semiconductor base material and a semiconductor layer.

FIG. 2 includes an illustration of a top view of the portion of the workpiece of FIG. 1 after forming mask members of a buried shield mask.

FIGS. 3 to 6 include illustrations of cross-sectional views of the workpiece of FIG. 2 after forming a buried shield and a deep portion of a source region.

FIGS. 7 to 10 include illustrations of cross-sectional views of the workpiece of FIGS. 3 to 6 after forming a carrier distribution layer, a carrier accumulation layer, a body region, and a shallow portion of the source region.

FIG. 11 includes an illustration of a top view of the portion of the workpiece of FIGS. 7 to 10 after forming a body contact/link mask.

FIGS. 12 to 15 include illustrations of cross-sectional views of the workpiece of FIG. 11 after forming body contact regions and link regions and removing the body contact/link mask.

FIG. 16 includes an illustration of a top view of the workpiece of FIGS. 12 to 15 after forming a gate trench mask.

FIGS. 17 to 20 include illustrations of cross-sectional views of the workpiece of FIG. 16 after patterning the substrate to define gate trenches and removing the gate trench mask.

FIG. 21 includes an illustration of a perspective view of the portion of the workpiece of FIGS. 17 to 20, wherein an upper surface of a portion of the workpiece within the view is centered about a body contact region.

FIG. 22 includes an illustration of a top view of the workpiece of FIGS. 17 to 20 after forming a gate dielectric layer, a gate conductive layer, and mask members for a gate mask.

FIGS. 23 to 26 include illustrations of cross-sectional views of the workpiece of FIG. 22 after forming gate members and removing the mask members of the gate mask.

FIG. 27 includes an illustration of a perspective view of a portion of the workpiece of FIGS. 23 to 26 corresponding to a unit cell.

FIG. 28 includes an illustration of a top view of the workpiece of FIGS. 23 to 26 after forming an interlevel dielectric layer and a contact mask.

FIGS. 29 to 32 include illustrations of cross-sectional views of the workpiece of FIG. 28 after removing the contact mask and after forming a source terminal.

FIG. 33 includes an illustration of a cross-sectional view of transistor structures to illustrate majority carrier flow from the source region to the semiconductor layer via a gap region.

Skilled artisans appreciate that elements in the figures are illustrated for simplicity and clarity and have not necessarily been drawn to scale. For example, the dimensions of some of the elements in the figures may be exaggerated relative to other elements to help to improve understanding of implementations of the inventive concepts.

### DETAILED DESCRIPTION

The following description in combination with the figures is provided to assist in understanding the teachings disclosed herein. The following description will focus on specific implementations of the teachings. This focus is provided to assist in describing the teachings and should not be interpreted as a limitation on the scope or applicability of the teachings. However, other implementations can be used based on the teachings as disclosed in this application.

As used in this specification, length and width are measured in directions along or parallel to a major surface of a substrate or a semiconductor layer. Depth, height, and thickness are measured in directions perpendicular to the major surface of the substrate or the semiconductor layer.

The term “electrically coupled” is intended to mean a connection, linking, or association of two or more electronic components, circuits, systems, or any combination of: (1) at least one electronic component, (2) at least one circuit, or (3) at least one system in such a way that a signal (e.g., current, voltage, or optical signal) may be partly or completely transferred from one to another. A subset of “electrically coupled” can include an electrical connection between two electronic components. In a circuit diagram, a node corresponds to an electrical connection between the electronic components. Thus, an electrical connection is a specific type of electrical coupling; however, not all electrical couplings are electrical connections. Other types of electrical coupling include capacitive coupling, resistive coupling, and inductive coupling.

The terms “horizontal,” “lateral,” and their variants are in directions along or parallel to a major surface of a substrate or semiconductor layer, and the terms “vertical,” “height,” “depth,” and their variants are in directions perpendicular to a major surface of the substrate or the semiconductor layer. Two objects that are laterally offset can be at the same or different elevations.

The term “normal operation” and “normal operating conditions” refer to conditions under which an electronic component or device is designed to operate. The conditions may be obtained from a data sheet or other information regarding voltages, currents, capacitance, resistance, or other electrical conditions. Thus, normal operation does not include operating an electrical component or device well beyond its design limits.

The terms “overlap,” “underlap,” and their variants refer to at least portions of regions or other features that lie along a vertical line that is perpendicular to a plane defined by a major surface. Components or features that overlap or underlap each other may or may not be in physical contact with each other.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements between the two elements.

The term “power transistor” is intended to mean a transistor that has a drain-to-source breakdown voltage (BV_{DS}) of at least 400 V.

Unless explicitly stated to the contrary, a border between a relatively heavier doped region or layer and an immediately adjacent and relatively lighter doped region or layer of the same conductivity type is where the dopant concentration between the regions or layers is 1.1 times higher than a peak dopant concentration of the relatively lower doped region or layer.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is used when describing elements, components and other features described herein. This is done merely for convenience and to give a general sense of the scope of the inventive concepts. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described.

Unless otherwise defined, all technical and scientific terms used herein have the same meaning as commonly understood by one of ordinary skill in the art to which these inventive concepts belongs. The materials, methods, and examples are illustrative only and not intended to be limiting. To the extent not described herein, many details regarding specific materials and processing acts are conventional and may be found in textbooks and other sources within the semiconductor and electronic arts.

An electronic device can include a buried shield and at least one gap region. In an implementation, a source region can include shallow and deep portions. A centerline through the gap region may pass through the shallow portion and not the deep portion. In the same or different implementation, the shallow portion may overlap all of the gap region, and the deep portion does not overlap the gap region. The drain-to-source punchthrough voltage can be higher than if the deep portion of the source region overlapped one or more gap regions due to a relatively thicker body region over the gap region as compared to another portion of the body region that is a channel region of a transistor structure. The deep portion can help to reduce source resistance and improve the threshold voltage control of a transistor structure. Thus, the electronic device can be designed to have a good balance between source contact resistance, threshold voltage control, and BV_{DS}.

In another implementation, the electronic device can include first and second gap regions. Lengths of the first and second gap regions can lie long lines that intersect each other. The design of the gap regions can help to reduce specific resistance (R_{SP}) by reducing a gap resistance for a power transistor, wherein the gap resistance corresponds to the gap regions. The gap regions can be designed such that the gap resistance is closer to a channel resistance corresponding to channel regions of transistor structures of the power transistor, as compared to all gap regions having lengths oriented along the same direction (for example, all lengths in the X-direction or all lengths in the Y-direction). In a particular implementation, the gap resistance can be within an order of magnitude of the channel resistance. After reading this specification, skilled artisans will be able to run simulations to determine the design of the gap regions that achieve transistor characteristics that meet the needs or desires for a particular application.

In the description below, doped layers and doped regions are described with respect to dopant concentrations and depths and vertical positions (in a direction perpendicular to a major surface) and lengths and widths (along the major surface or a plane parallel to the major surface).

Skilled artisans will be able to perform simulations to determine doses and energies to be used at the time of doping to achieve the doped layers and doped regions in the finished device.

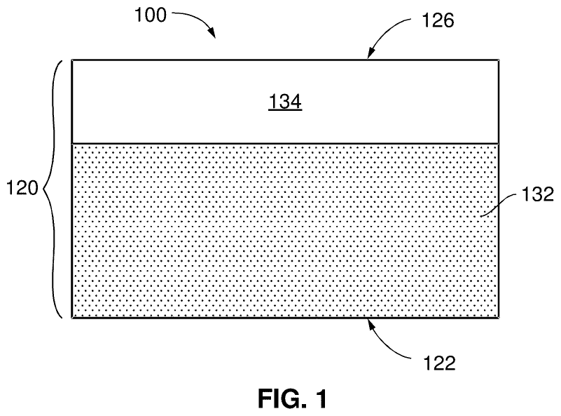

FIG. 1 includes a cross-sectional view of a portion of a substrate 120 that can include a semiconductor base material 132 and a semiconductor layer 134. The semiconductor base material 132 can be a monocrystalline semiconductor wafer, a semiconductor-on-insulator (SOI) wafer, or the like. In an implementation, the semiconductor base material 132 can be in a form of a wafer. The semiconductor base material 132 and the semiconductor layer 134 can include a wide bandgap semiconductor material, and in a particular implementation, SiC is the semiconductor material within the semiconductor layer 134 and is the semiconductor material within at least the portion of the semiconductor base material 132 that contacts the semiconductor layer 134. In an implementation, the SiC can be a 3C, a 4H, or a 6H polytype.

The semiconductor material within the semiconductor base material 132 can be a drain region for the power transistor and have a dopant concentration of at least 1×10¹⁸ atoms/cm³. In a particular implementation, the dopant concentration can be at least 1×10¹⁹ atoms/cm³ to ensure an ohmic contact to a drain electrode that is subsequently attached to or formed along a back side major surface 122. The semiconductor base material 132 may have a peak dopant concentration that is at most 2×10²¹ atoms/cm³. The semiconductor material within the semiconductor base material 132 can be n-type doped or p-type doped. The majority carriers for the power transistor can be electrons, and the semiconductor material can be n-type doped. In this specification, n-type dopants can be N or P, and a p-type dopant can be Al.

The semiconductor layer 134 can be epitaxially grown and doped during or after growth. The semiconductor layer 134 can have a thickness in a range from 4.0 microns to 20.0 microns. The semiconductor layer 134 can have the same conductivity type as the semiconductor material within the semiconductor base material 132. In an implementation, the semiconductor layer 134 is n-type doped. The semiconductor layer 134 can be a drift region for the power transistor and have a lower dopant concentration as compared to the semiconductor material within the semiconductor base material 132. The average dopant concentration of the semiconductor layer 134 can be in a range from 2×10¹⁵ atoms/cm³ to 4×10¹⁶ atoms/cm³. The average dopant concentration of the semiconductor layer 134 before any further doping, such as for a body region or a source region, is referred to herein as the original dopant concentration for the semiconductor layer 134.

One or more epitaxial layers may be grown between semiconductor base material 132 and semiconductor layer 134. These additional layers may serve a number of functions including, such as, providing a transition buffer at the start of epitaxial growth, a layer for isolating crystal defects from the semiconductor layer 134, or a layer for improving stability at high current operation (i.e., safe operating area improvement). In these aforementioned cases, the additional layers usually have a higher doping concentration than semiconductor layer 134, have low resistivity because of their high doping concentration, and provide little additional benefit in blocking voltage.

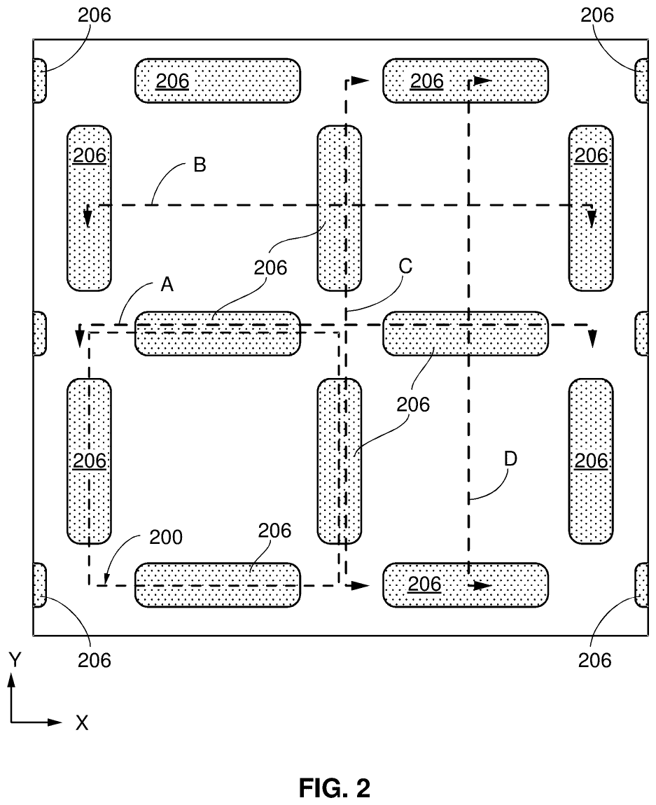

FIG. 2 includes a top view of a buried shield mask that includes mask members 206. The mask members 206 correspond to locations where gap regions will be formed. In the finished power transistor structures, electrons can flow through the gap regions when the power transistor is on. In this specification, some masks will be described as hard masks, such as the buried shield mask here. Other masks will be described as photoresist masks. In a hard mask, a pattern is first defined in photoresist and then transferred by etching to an underlying masking layer comprising either a single film or a plurality of films of oxide, nitride, polycrystalline silicon (polysilicon), or similar materials. This type of mask is referred to as a hard mask because it can withstand higher processing temperatures than photoresist, which is often needed when performing ion implantation into SiC. The need for high temperature ion implantation (for example, higher than room temperature, or 20° C. to 25° C.) increases with both the energy and dose of the implanted species. Depending upon the implant conditions, both photoresist masks and hard masks can sometimes be used interchangeably. Accordingly, the use of either a photoresist mask or a hard mask in this specification is for illustrative purposes only and should not be construed as a limitation on the invention.

In FIG. 2, not all the mask members 206 are identified with reference numbers to simplify understanding of the mask design. The power transistor that is being formed includes many unit cells, where one of the units cells 200 is identified in FIG. 2. Many other unit cells are present but not identified in FIG. 2. The unit cells that are immediately adjacent to the right, left, above and below the unit cell 200 are mirror images of the unit cell 200. Locations not covered by the mask members 206 will be implanted to form a buried shield.

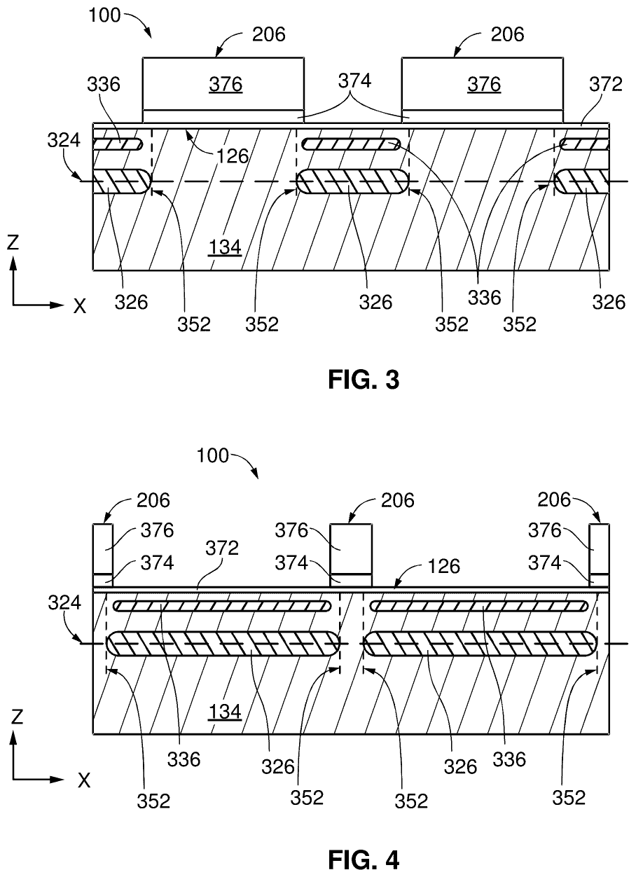

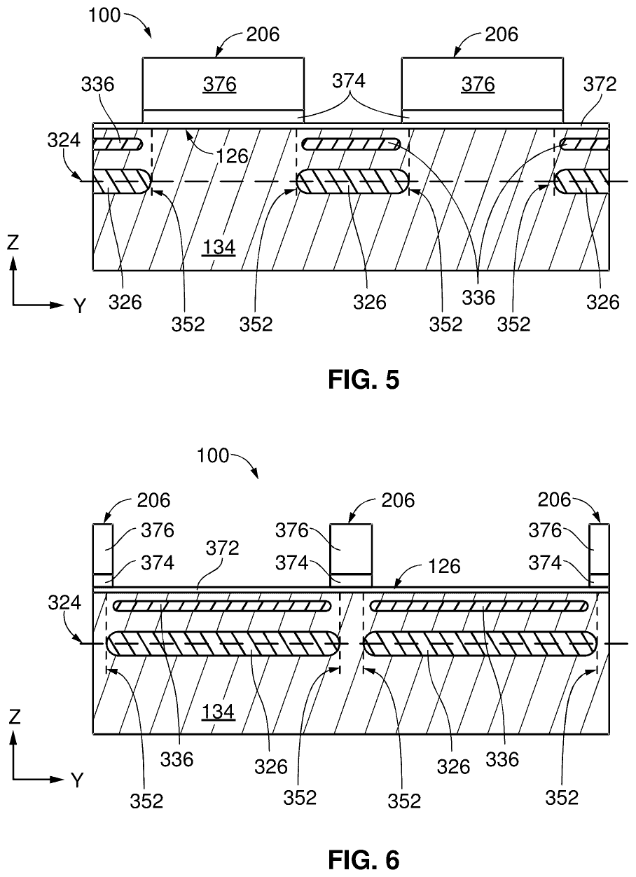

FIGS. 3 to 6 include cross-sectional views of a portion of a workpiece 100 that includes the substrate 120 after a buried shield 326 and a deep portion 336 of a source region are formed. FIG. 3 is along the sectioning line A in FIG. 2, FIG. 4 is along the sectioning line B in FIG. 2, FIG. 5 is along the sectioning line C in FIG. 2, and FIG. 6 is along the sectioning line D in FIG. 2.

In this specification, doping for each layer or region can be performed as a single ion implantation or as a plurality of ion implantations where each ion implant is performed at a different energy as compared to one or more other ion implantations within the plurality of ion implantations. After reading this specification, for each doping, skilled artisans will be able to determine the number of ion implantations, dose(s), and energy(ies) for a particular doping species (e.g., N (n-type), P (n-type), or Al (p-type)) to achieve desired doping depth(s) and a dopant concentration profile.

Referring to FIGS. 3 to 6, the buried shield mask can include a relatively thinner oxide layer 372, a polysilicon layer 374, and a relatively thicker oxide layer 376. Of the three layers, the substrate is closest to the relatively thinner oxide layer 372 and farthest from the relatively thicker oxide layer 376. The relatively thinner oxide layer 372 can have a thickness in range from 10 nm to 90 nm. In the same or different implementation, the polysilicon layer 374 can have a thickness in a range from 30 nm to 300 nm. In the same or a further different implementation, the relatively thicker oxide layer 376 can have a thickness in a range from 0.9 micron to 4.0 microns. The polysilicon layer 374 and the relatively thicker oxide layer 376 can be patterned to form the mask members 206, and the relatively thinner oxide layer 372 can remain unpatterned during implantation. The relatively thinner oxide layer 372 can help to reduce the likelihood of implant channeling within the monocrystalline SiC when doping to form the buried shield 326. Also, for SiC, higher dose implants can be performed at elevated temperatures to reduce implant damage. The hard mask can allow a temperature for the ion implantation that conventional photoresist materials may not withstand.

A buried shield 326 helps to shield subsequently-formed gate electrodes from the drain voltage of the power transistor and can be used to limit or reduce the saturation current of the power transistor during a short-circuit event. The ability to survive short-circuit events on the order of several microseconds can be important for some applications such as motor drives and traction inverters. Limiting this current during a short-circuit event can extend the survival time for the power transistor. A mid-elevation line 324 is where half of a thickness of the buried shield 326 is above the mid-elevation line 324, and the other half of the thickness of buried shield 326 is below the mid-elevation line 324.

The buried shield 326 has the opposite conductivity type as compared to the semiconductor layer 134. In an implementation, the buried shield 326 can be p-type doped. The peak dopant concentration of the buried shield 326 can be the same or different from the peak dopant concentration of a subsequently-formed body region. In the same or different implementation, a peak dopant concentration of the buried shield 326 can be in a range from 8×10¹⁷ atoms/cm³ to 2×10¹⁹ atoms/cm³. In the same or a further implementation, the peak dopant concentration for the buried shield 326 can be at an elevation in a range from 0.3 microns to 0.9 microns below the major surface 126.

The buried shield 326 may not fully deplete during reverse bias under normal operating conditions. However, unlike the subsequently-formed body region which can influence the threshold voltage of a subsequently formed transistor, fewer electrical characteristics of the power transistor may depend upon the buried shield 326. Therefore, the buried shield 326 can have a higher dopant concentration than the subsequently-formed body region, even beyond the 2×10¹⁹ atoms/cm³ limit recited above. Concentrations above this limit may be possible but may not significantly improve the drain voltage shielding properties of the buried shield 326.

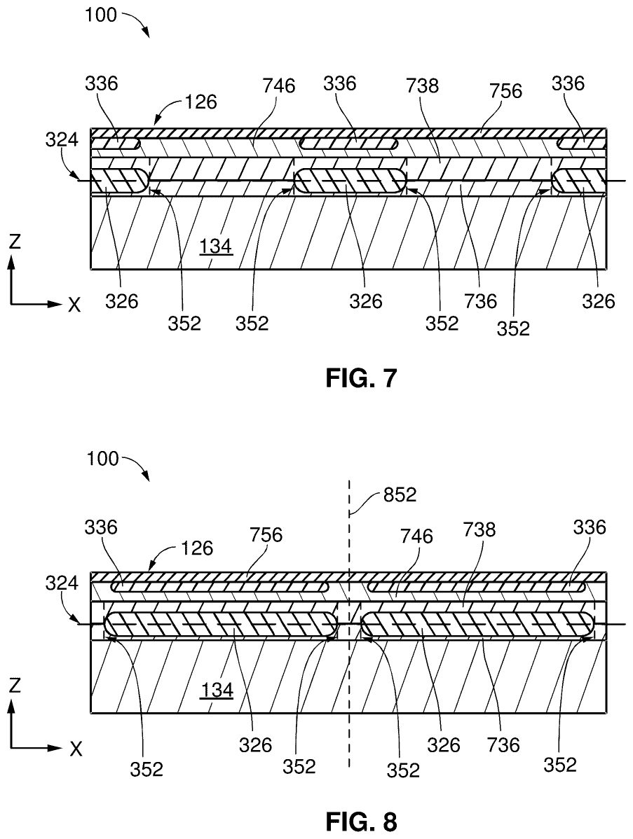

The deep portion 336 of the source region can help to keep resistance in the source region relatively low as compared to a source region that does not include the deep portion 336. A subsequently-formed shallow portion of a source region described in more detail with respect to FIGS. 7 to 10 occupies substantially all of a cell array for the power transistor. Unlike the shallow portion of the source region, the mask members 206 block the deep portion 336 from being formed across all of the cell array. The significance of the pattern for the deep portion 336 will be described in more detail with respect to gap regions in FIGS. 7 to 10.

The deep portion 336 can have the same conductivity type as the semiconductor layer 134. In an implementation, the deep portion 336 can be n-type doped. The deep portion 336 can have a peak dopant concentration of at least 5×10¹⁸ atoms/cm³. In an implementation, the deep portion 336 can have a peak dopant concentration of at least 1×10¹⁹ atoms/cm³ to ensure lower resistance within the source region. In the same or different implementation, the peak dopant concentration may be at most 5×10²⁰ atoms/cm³, so that subsequently-formed body contact regions can be formed and counter dope portions of the deep portion 336. In the same or a different implementation, the deep portion 336 may extend from the major surface 126 to a depth in a range from 0.1 micron to 0.4 micron. In a particular implementation as illustrated in FIGS. 3 to 6, the deep portion 336 is spaced apart and does not contact the major surface 126.

Ion implant scattering may cause some of the dopant for each of the deep portion 336 and the buried shield 326 to extend laterally under portions of the mask members 206. As compared to the deep portion 336, the buried shield 326 can extend farther under the mask members 206 because the implant energy when forming the buried shield 326 can be greater than the implant energy when forming the deep portion 336. Thus, the buried shield 326 can underlap all of the deep portion 336.

Gap regions 352 (illustrated with dashed lines) are regions where the conductivity type corresponds to the majority carriers for the power transistor (e.g., n-type when majority carriers are electrons, or p-type when majority carriers are holes) and are at least partly defined by the buried shield 326. The deep portion 336 of the source region does not extend into or overlap any one or more of the gap regions 352. From a plan view, the gap regions 352 have shapes that correspond to the mask members 206 in FIG. 2. Each of the gap regions 352 can have a length and a width, where the length is greater than the width. The lengths of some of the gap regions 352 lie along lines in the X-direction, and the lengths of other gap regions 352 lie along lines in the Y-direction. The lines in the X-direction can be substantially orthogonal to the lines in the Y-direction. In an implementation, the lines in the X-direction intersect the lines in the Y-direction at an angle that is 90°+/−5°. The widths of the gap regions 352 are in a range from 0.4 micron to 3.0 microns, as measured in a direction that is parallel to the major surface 126 and perpendicular to a gate trench depth of subsequently-formed gate trenches. The unit cell 200 can include parts of four different gap regions 352.

In another implementation, when the buried shield mask is a hard mask, a spacer can be formed along the mask members 306 after the implantation of the buried shield 326 and before the implantation of the deep portion 336 of the source region. The spacer may be formed by depositing any of the materials described for the hard mask followed by an anisotropic etch so that a portion of the deposited film remains along a sidewall of the hard mask. When the implantation of the subsequent deep portion 336 of the source region is performed, the edge of the implanted region can be further spaced apart from gap regions 352 by a distance approximately equal to the width of the spacer along the base of the spacer. This spacer can be removed at the same time the hard mask is removed.

In still another implementation, different masks may be used to form the buried shield 326 and the deep portion 336 of the source region. The deep portion 336 may extend laterally farther from, closer to, or into the gap regions 352 as compared to the implementation as illustrated in FIGS. 3 to 6. The deep portion 336 does not extend across all of any one or more of the gap regions 352. Drain-to-source breakdown voltage (BV_{DS}) improvement may be achieved by the deep portion 336 not extending across all of any one or more of the gap regions 352. Referring to FIGS. 3 to 6, from a top view, as less area is occupied by the deep portion 336, BV_{DS} can increase to only a point, and further reduction of area occupied by the deep portion 336 does not significantly increase BV_{DS}. However, as the area continues to be reduced, resistance attributed to the source region can increase. Thus, the area of the deep portion 336 may be reduced only to the point at which no further significant increase in BV_{DS} occurs. After reading this specification, skilled artisans will be able to run simulations to determine an area occupied by the deep portion 336 that allows the power transistor to have acceptable values for BV_{DS} and source resistance.

The mask members 206 and any sidewall spacers can be removed after the deep portion 336 of the source region and the buried shield 326 are formed. The relatively thinner oxide layer 372 may or may not be removed at this point in the process.

A body mask (not illustrated) can be formed over the major surface 126 of the semiconductor layer 134. The active area for transistor structures of the power transistor being formed is exposed. The mask covers areas where electronic components and circuits are outside the active area for the transistor structures. The body mask is used when forming a carrier distribution layer 736, a carrier accumulation region 738, a body region 746, and a shallow portion 756 of the source region.

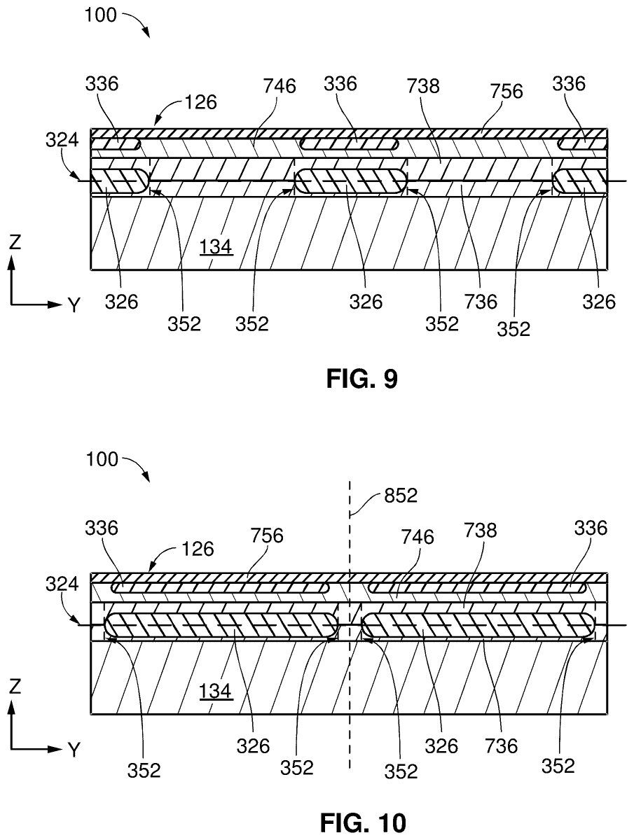

Referring to FIGS. 7 to 10, doping can be performed to form the carrier distribution layer 736, the carrier accumulation region 738, the body region 746, and the shallow portion 756 of the source region. FIG. 7 is along the sectioning line A as illustrated in FIG. 2, FIG. 8 is along the sectioning line B as illustrated in FIG. 2, FIG. 9 is along the sectioning line C as illustrated in FIG. 2, and FIG. 10 is along the sectioning line D as illustrated in FIG. 2. Formation of the carrier distribution layer 736, the carrier accumulation region 738, the body region 746, and the shallow portion 756 of the source region can be performed in any order relative to one another.

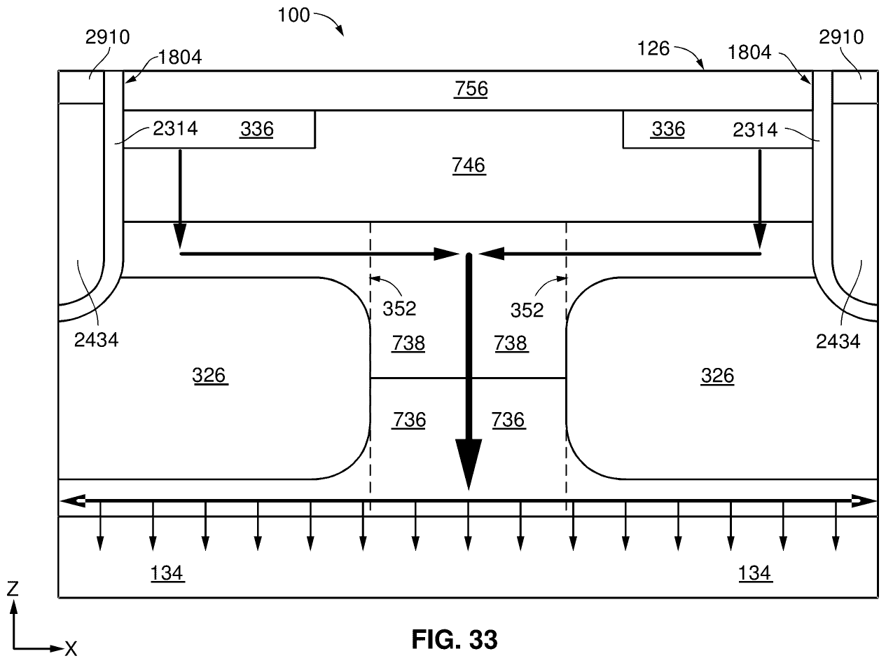

The gap regions 352 can include portions of carrier distribution layer 736 and the carrier accumulation region 738 between portions of the buried shield 326. As will be described in more detail with respect to FIG. 33, majority carriers can flow along a path through the carrier accumulation region 738, around the buried shield 326 into the gap regions 352, through the carrier distribution layer 736, and into to the semiconductor layer 134. At least a portion of the carrier distribution layer 736 may underlap the carrier accumulation region 738. In an implementation, part or all of the carrier distribution layer 736 can underlap the carrier accumulation region 738.

The border between the carrier distribution layer 736 and the carrier accumulation region 738 can be at any elevation between an uppermost elevation of the buried shield 326 and a lowermost elevation of the buried shield 326 within the unit cell 200. In a particular implementation, the border between the carrier distribution layer 736 and the carrier accumulation region 738 can be at or near the mid-elevation line 324.

On a relative basis, the peak dopant concentration of the buried shield 326 can be greater than each of the peak dopant concentrations of the carrier distribution layer 736 and the carrier accumulation region 738. The peak dopant concentration of the carrier distribution layer 736 can be the same or less than the peak dopant concentration of the carrier accumulation region 738.

The carrier accumulation region 738 can help majority carriers flow from channel regions of transistor structures of the power transistor to the gap regions 352. The carrier accumulation region 738 can be located between the body region 746 and the buried shield 326. The carrier accumulation region 738 can extend at least partly within the gap regions 352. The carrier accumulation region 738 may extend across all of the width of the gap regions 352 within the active region of the power transistor.

In an implementation, all of the buried shield 326 underlaps a portion of the carrier accumulation region 738; however, the buried shield 326 does not underlap all of the carrier accumulation region 738. In the same or different implementation, for the array of transistor structures of the power transistor, the buried shield 326 underlaps at least 10% of the carrier accumulation region 738. As the amount of underlap increases, the ability to survive a short-circuit event improves. Thus, the underlap can be at least 40% or at least 70%. When the underlap becomes too great, R_{SP} may become higher than desired. In the same or different implementation, the buried shield 326 underlaps at most 99%, at most 98%, or at most 95% of the carrier accumulation region 738. In any of the preceding or different implementations, the buried shield 326 underlaps in a range of 70% to 95% of the carrier accumulation region 738.

The carrier accumulation region 738 can fully deplete during reverse bias under normal operating conditions. In an implementation, the carrier accumulation region 738 can fully deplete when any or all of the gap regions 352 are not fully depleted.

In a finished device, the carrier accumulation region 738 can be at an elevation that is at least 0.3 microns below the major surface 126 and may be up to 1.5 microns below the major surface 126. The carrier accumulation region 738 can have a thickness (measured in the Z-direction) in a range from 0.2 micron to 0.5 micron.

The peak dopant concentration of the carrier accumulation region 738 can be in a range from 2×10¹⁷ atoms/cm³ to 4×10¹⁸ atoms/cm³. In the same or different implementation, the carrier accumulation region 738 may have a dopant concentration gradient where a dopant concentration of the carrier accumulation region 738 at a location closer to the carrier distribution layer 736 is less than a dopant concentration of the carrier accumulation region 738 at a different location closer to body region 746.

The carrier distribution layer 736 can help to redistribute majority carriers along a flow path from the carrier accumulation region 738 to the semiconductor layer 134 via the gap regions 352. The carrier distribution layer 736 can extend into the gap regions 352. In an implementation, all of the buried shield 326 overlaps a portion of the carrier distribution layer 736; however, the buried shield 326 does not overlap all of the carrier distribution layer 736. In the same or different implementation, for the array of transistor structures of the power transistor, the buried shield 326 overlaps at least 10% of the carrier distribution layer 736 that lies below the mid-elevation line 324. As the amount of overlap increases, the ability to survive a short-circuit event improves. Thus, the overlap can be at least 40% or at least 70%. When the overlap becomes too great, R_{SP} may become higher than desired. In the same or different implementation, the buried shield 326 overlaps at most 99%, at most 98%, or at most 95% of the carrier distribution layer 736. In any of the preceding or different implementations, the buried shield 326 overlaps in a range of 70% to 95% of the carrier distribution layer 736.

The carrier distribution layer 736 has the same conductivity type as the semiconductor layer 134. The carrier distribution layer 736 can be n-type doped when the majority carriers are electrons. The carrier distribution layer 736 can fully deplete during reverse bias under normal operating conditions.

The carrier distribution layer 736 can have a peak dopant concentration that is greater than the average dopant concentration of the semiconductor layer 134. In an implementation, the peak dopant concentration can be less than an order of magnitude higher than the average dopant concentration of the semiconductor layer 134. The carrier distribution layer 736 can have a peak dopant concentration that is in a range from 4×10¹⁶ atoms/cm³ to 8×10¹⁷ cm³. The peak dopant concentration for the carrier distribution layer 736 can be at an elevation that is 0.7 microns to 2.0 microns below the major surface 126.

In a particular implementation, the dopant concentration for the carrier distribution layer 736 may have a dopant concentration gradient where a dopant concentration of the carrier distribution layer 736 at a location closer to the carrier accumulation region 738 is greater than a dopant concentration of the carrier distribution layer 736 at a different location closer to semiconductor base material 132.

The body region 746 includes channel regions for the transistor structures of the power transistor. The body region 746 has a conductivity type that is opposite any one or more of the semiconductor layer 134, the carrier distribution layer 736, or the carrier accumulation region 738. In an implementation, the body region 746 can be p-type doped. The buried shield 326 is spaced apart from the body region 746 by at least a portion of the carrier accumulation region 738. The body region 746 can underlap the source region, including the shallow portion 756 and the deep portion 336. A portion of the body region 746 does not underlap the deep portion of the source region. The body region 746 can overlap the carrier accumulation region 738.

A peak dopant concentration of the body region 746 is greater than the average dopant concentration of the semiconductor layer 134, the carrier distribution layer 736, or both. In an implementation, the peak dopant concentration is in a range from 8×10¹⁷ atoms/cm³ to 8×10¹⁸ atoms/cm³. A peak dopant concentration for the body region 746 can be at an elevation that is in a range from 0.1 microns to 0.6 microns below the major surface 126. Unlike the carrier distribution layer 736 and the carrier accumulation region 738, the body region 746 may not fully deplete during reverse bias under normal operating conditions. These depletion conditions for the carrier distribution layer 736 and the carrier accumulation region 738 can be used to determine their maximum dopant concentrations for a given device geometry, and the depletion condition for the body region 746 can be used to determine a lower value for the dopant concentration for a given device geometry.

The source region for the power transistor can include the shallow portion 756 and the deep portion 336. The shallow portion 756 can have the same conductivity type as the deep portion 336 of the source region, the carrier accumulation region 738, the carrier distribution layer 736. In an implementation, the shallow portion 756 can be n-type doped. The shallow portion 756 is thinner (as measured in the Z-direction) as compared to the part of the source region that includes the deep portion 336 and the shallow portion 756.

The shallow portion 756 can overlap the gap regions 352. The shallow portion 756 does not extend as far into the substrate as compared to the deep portion 336. Thus, the body region 746 is locally thicker where it overlaps the gap regions 352 and is locally thinner where it underlaps the deep portion 336 of the source region. In an implementation, a centerline 852 can pass through a center of the narrowest widths of the gap regions 352, wherein the centerline 852 is perpendicular to the major surface 126. The width may be measured at or near the mid-elevation line 324. The centerline 852 can pass through the shallow portion 756 of the source region and does not pass through the deep portion 336 of the source region. Based on simulations, the breakdown mechanism can occur by drain-to-source punchthrough at the gap regions 352 in a direction generally along or parallel to the centerline 852 because, as compared to other regions and layers, the body region 746 is exposed to the highest potential during reverse bias. The body region 746 is locally thicker where it overlaps the gap regions 352 and can allow BVDS to be higher than if the deep portion 336 overlapped all of any one or more of the gap regions 352.

In an implementation, the shallow portion 756 can extend from the major surface 126 to a depth that is at most 75%, at most 65%, or at most 55% of the lowermost elevation of the deep portion 336. In the same or different implementation, the shallow portion 756 can extend from the major surface 126 to a depth that is at least 20%, at most 25%, or at most 30% of the lowermost elevation of the deep portion 336. In either or both implementations, the shallow portion 756 can extend from the major surface 126 to a depth that is in a range from 20% to 75%, 25% to 65%, or 30% to 55% of the lowermost elevation of the deep portion 336. The shallow portion 756 may extend to a depth that is in a range from 0.05 micron to 0.3 micron from the major surface 126.

The peak dopant concentration of the shallow portion 756 can be any of the peak dopant concentrations previously described with respect to the deep portion 336. In an implementation, the shallow portion 756 and the deep portion 336 can have the same peak dopant concentration or different peak dopant concentrations.

The body mask can be removed after the carrier distribution layer 736, the carrier accumulation region 738, the body region 746, and the shallow portion 756 are formed.

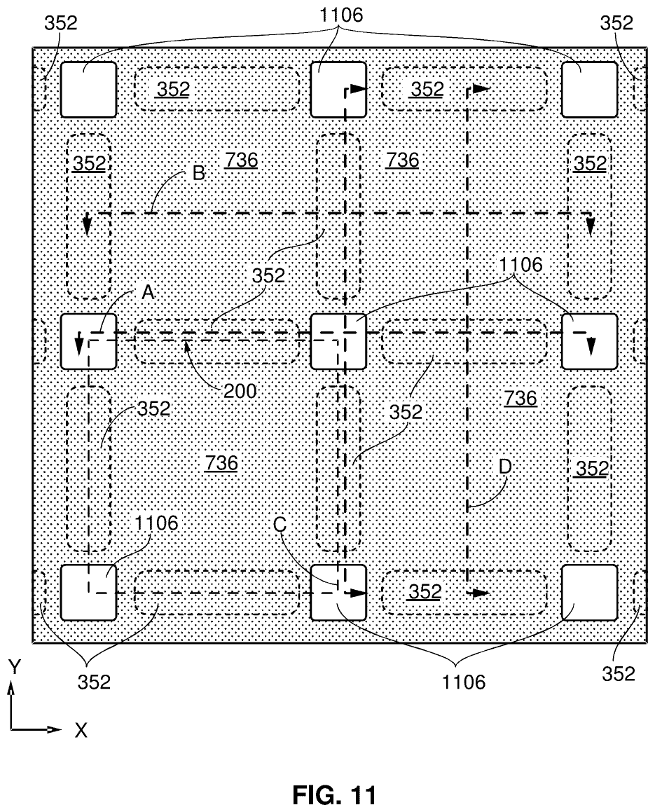

FIG. 11 includes a top view of a body contact/link mask 1100. The body contact/link mask 1100 can be formed and define openings 1106 for body contact regions and link regions. The body contact/link mask 1100 overlaps the shallow portion 756 of the source region. The gap regions 352 can underlap the shallow portion 756 of the source region and are spaced apart from the major surface 126. The gap regions 352 are illustrated to provide a better understanding of positional relationships between the gap regions 352 and the openings 1106. In FIG. 11, not all the openings 1106 and gap regions 352 are identified with reference numbers to simplify understanding of the mask design.

The body contact/link mask 1100 can have the same or a different composition as previously described with respect to the mask members 206 in FIG. 2. In an implementation, the body contact/link mask 1100 can be made from an oxide layer similar to the relatively thicker oxide layer 376 previously described, and thus, the relatively thinner oxide layer 372, the polysilicon layer 374, or both may or may not be present. In a further implementation, the body contact/link mask 1100 can be made of photoresist.

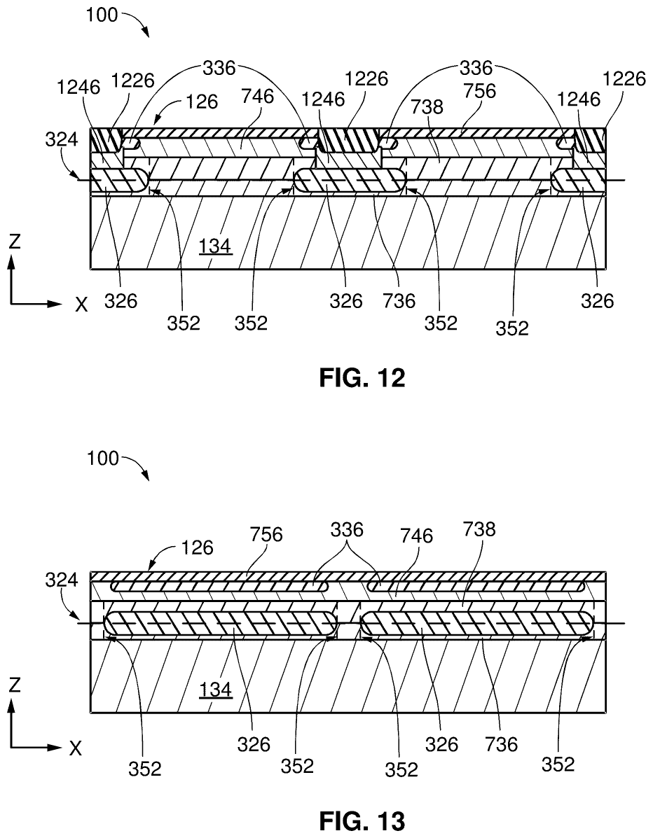

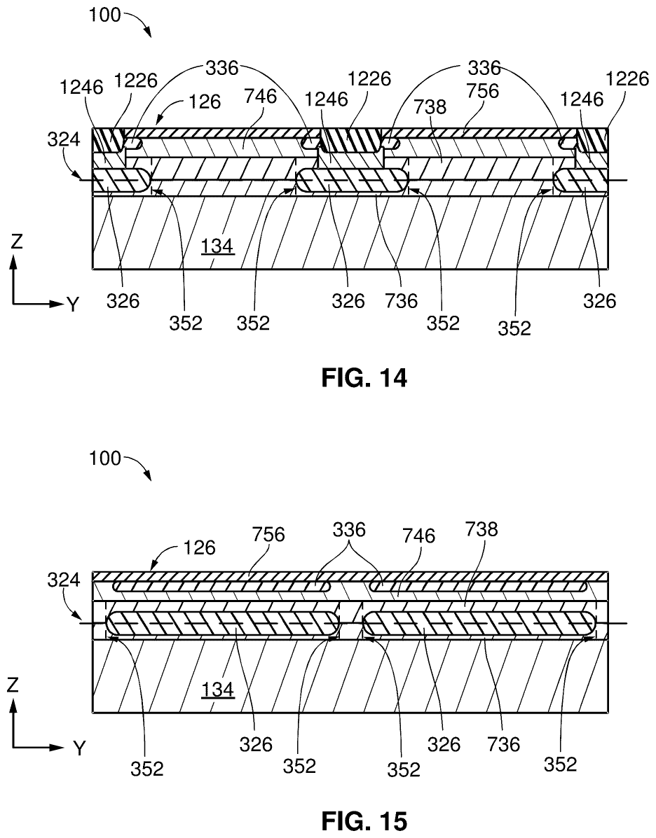

FIGS. 12 to 15 include cross-sectional views of the workpiece 100 after body contact regions 1226 and link regions 1246 are formed and the body contact/link mask 1100 is removed. FIG. 12 is along the sectioning line A in FIG. 11, FIG. 13 is along the sectioning line B in FIG. 11, FIG. 14 is along the sectioning line C in FIG. 11, and FIG. 15 is along the sectioning line D in FIG. 11.

The body contact regions 1226 can be electrically coupled to the body region 746 and the buried shield 326 via the link regions 1246. In an implementation, the body contact regions 1226 can be electrically connected to the body region 746 and the buried shield 326 via the link regions 1246. Any one or more of the body contact regions 1226 may physically contact the body region 746 (physical contact not illustrated) or may be spaced apart from and not contact the body region (illustrated in FIGS. 12 and 14). In a particular implementation, the body contact regions 1226 can be electrically connected to a subsequently-formed source terminal. The body contact regions 1226 are formed below the openings 1106 of the body contact/link mask 1100 in FIG. 11. The body contact regions 1226 have the same conductivity type as the body region 746 and the buried shield 326. In an implementation, the body contact regions 1226 are p-type doped.

The body contact regions 1226 can physically contact and extend through the shallow portion 756 and the deep portion 336 of the source region, and thus, lowermost elevations of the body contact regions 1226 can lie below a lowermost elevation of the deep portion 336 of the source region within the active region for the power transistor. At a location spaced apart from the body contact regions 1226, the shallow portion 756 of the source region does not overlap the deep portion 336 of the source region. The body contact regions 1226 may not extend to the buried shield 326.

The body contact regions 1226 can have a peak dopant concentration that is greater than the peak dopant concentration of the shallow portion 756 and the deep portion 336 of the source region. In the same or different implementation, the body contact regions 1226 have a peak dopant concentration of at least 1×10¹⁹ atoms/cm³ and may have a peak dopant concentration that is at most 2×10²¹ atoms/cm³. In an implementation, the body contact regions 1226 extend from the major surface 126 to a depth in a range from 0.3 micron to 0.7 micron.

The link regions 1246 electrically couple the buried shield 326 and the body contact regions 1226 to one another. In an implementation, the buried shield 326 and the body contact regions 1226 are electrically connected to one another via the link regions 1246. In the same or different implementation, the link regions 1246 physically contact the buried shield 326 and the body contact regions 1226. Each of the link regions 1246 has a corresponding body contact region 1226, wherein such body contact region 1226 overlaps the particular link region 1246 that overlaps the buried shield 326.

The link regions 1246 can extend through the portions of the carrier accumulation region 738 and to any depth within the buried shield 326. In an implementation, the link regions 1246 can extend to a depth in a range from 0.4 micron to 0.9 micron from the major surface 126. The link regions 1246 may contact the body region 746 (illustrated in FIGS. 12 and 14) or may not contact the body region 746 (not illustrated).

The link regions 1246 have the same conductivity type as the buried shield 326 and the body contact regions 1226. The link regions 1246 have a peak dopant concentration that is greater than the peak dopant concentrations of the carrier accumulation region 738 and may or may not have a peak dopant concentration that is less than the peak dopant concentration of any one or more of the shallow portion 756 and the deep portion 336 of the source region and the buried shield 326. In the same or different implementation, the peak dopant concentration of the link regions 1246 can be less than the peak dopant concentration of the body contact regions 1226. In the same or a further different implementation, the link regions 1246 can have a peak dopant concentration in a range from 1×10¹⁷ atoms/cm³ to 1×10¹⁹ atoms/cm³.

An anneal can be performed to activate dopants with respect to the previously described doping operations. Before performing the anneal, a graphite capping layer can be formed over the workpiece to protect the SiC surface from sublimation, pitting and other forms of surface roughening during the anneal. In an implementation, the graphite capping layer can have a thickness in a range from 1.5 microns to 5.0 microns. The capping layer can be deposited in the form of photoresist and decomposed to a layer primarily composed of carbon during the subsequent anneal. The anneal can be performed for a soak time in a range from 10 minutes to 60 minutes at a temperature in a range from 1500° C. to 1800° C. The dopants within the workpiece may not significantly diffuse during the anneal, and thus, the doped layers and doped regions substantially may retain their shapes and locations as originally formed. In an implementation, the anneal can be performed in an inert ambient.

The anneal can be performed before or after forming gate trenches as described below. The anneal can be performed before forming a gate dielectric layer because a material within the gate dielectric layer may not be able to withstand the temperature used for the anneal. After reading this specification, skilled artisans will be able to determine where in the process flow the anneal is performed.

Many doping operations have been described previously. The order of performing the doping operations after forming the semiconductor layer 134 can be changed. For example, doping for the body contact regions 1226 could be performed before many of the other doping operations previously described, such as doping for the carrier distribution layer 736, the carrier accumulation region 738, the body region 746, and shallow portion 756 and the deep portion 336 of the source region. Thus, before any anneal is performed, the doping operations can be performed in many different orders. In another implementation, another anneal may be performed after some but not all doping operations. Any doping operations performed before the other anneal is performed may not be performed after the other anneal, and any doping operations after the other anneal is performed may not be performed before the other anneal.

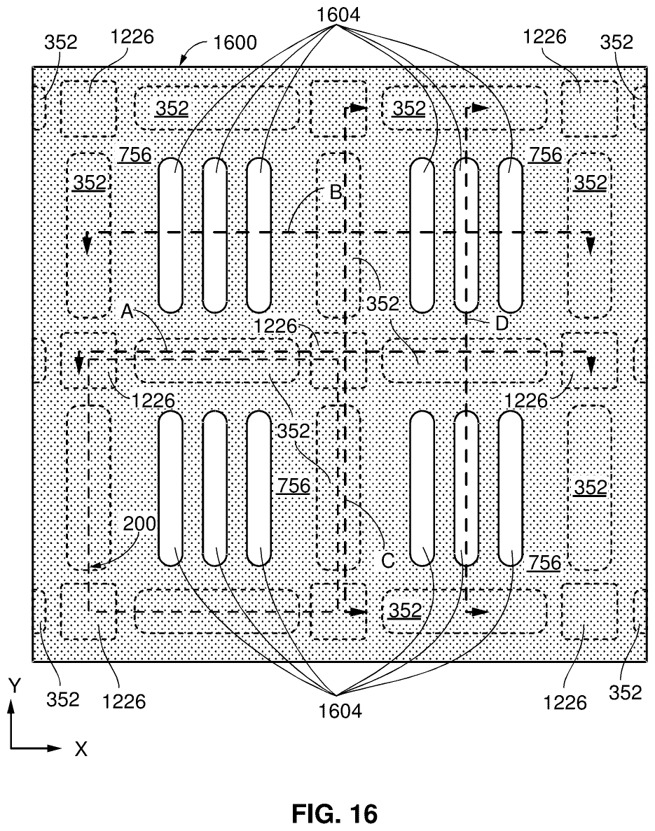

FIG. 16 includes a top view of a gate trench mask 1600 over the workpiece 100. The gate trench mask 1600 defines gate trench openings 1604 that are used to define gate trenches. The gate trench openings 1604 can be in the form of stripes that have lengths that are in the Y-direction. The gate trench mask 1600 can have the same or a different composition as previously described with respect to the buried shield mask. In an implementation, the gate trench mask 1600 can be made from an oxide layer similar to the relatively thicker oxide layer 376 previously described, and thus, the relatively thinner oxide layer 372, the polysilicon layer 374, or both may or may not be present. In another implementation, the gate trench mask 1600 can be made of photoresist.

Some features are illustrated in FIG. 16 to assist in understanding the layout. The gate trench mask 1600 overlaps the shallow portion 756 of the source region, body contact regions 1226, and the gap regions 352. The gate trench openings 1604 expose portions of the shallow portion 756 of the source region. The body contact regions 1226 and the gap regions 352 are illustrated with dashed lines. Some, but not all, body contact regions 1226 and the gap regions 352 are labelled in FIG. 16. The shallow portion 756 of the source region and the body contact regions 1226 can lie at the major surface 126 (labelled in FIGS. 12 and 14). The gap regions 352 are farther into the workpiece 100 and spaced apart from the major surface 126.

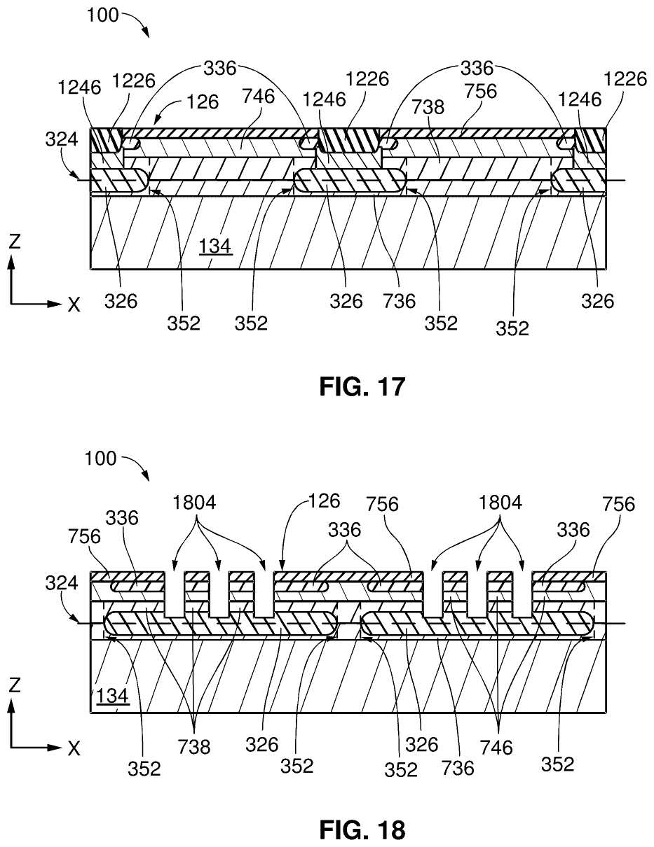

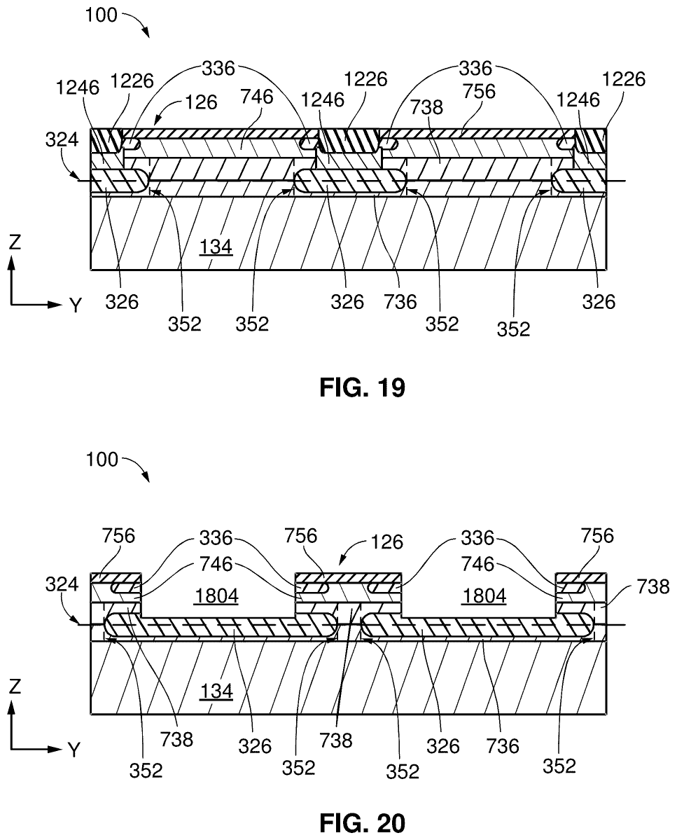

FIGS. 17 to 20 include cross-sectional views of the workpiece 100 after defining gate trenches 1804 and removing the gate trench mask 1600. FIG. 17 is along the sectioning line A in FIG. 16, FIG. 18 is along the sectioning line B in FIG. 16, FIG. 19 is along the sectioning line C in FIG. 16, and FIG. 20 is along the sectioning line D in FIG. 16.

The semiconductor material below the gate trench openings 1604 of the gate trench mask 1600 is etched to define the gate trenches 1804 that extend to a gate trench depth from the major surface 126. Referring to FIGS. 18 and 20, the gate trenches 1804 can extend from the major surface 126 through the shallow portion 756 and the deep portion 336 of the source region and the body region 746 and to at least the carrier accumulation region 738. The gate trenches 1804 can physically contact the carrier accumulation region 738. The shallow portion 756 and the deep portion 336 of the source region, the body region 746, and at least a portion of the carrier accumulation region 738 can lie along sidewalls of the gate trenches 1804.

In an implementation, the gate trenches 1804 can extend through the carrier accumulation region 738 and into the buried shield 326 as illustrated in FIGS. 18 and 20. Channel lengths of transistor structures of the power transistor can correspond to the thickness of the body region 746 along the sidewalls of the gate trenches 1804. The buried shield 326 can underlap at least a portion of the body region 746 and the gate trenches 1804. In the same or different implementation, the gate trenches 1804 do not extend completely through the buried shield 326. In the same or a more particular implementation, the gate trenches 1804 are spaced apart from and do not physically contact (1) a portion of the carrier distribution layer 736 beneath the buried shield 326, (2) the underlying semiconductor layer 134 or both (1) and (2). In any of the implementations, the depths of the gate trenches 1804 can be in a range from 0.3 micron to 1.1 microns. In another implementation, the bottoms of the gate trenches 1804 may be at an elevation as deep as 0.05 micron from the top of the carrier accumulation region 738. In any of the foregoing or a different implementation, the buried shield 326 can underlap at least a portion of the body region 746 and the gate trenches 1804.

Widths of the gate trenches 1804 correspond to the widths of the gate trench openings 1604 that are measured in the X-direction in FIG. 16. The widths of the gate trenches 1804 can be the same or different from one another. In an implementation, the widths of the gate trenches 1804 can be in a range from 0.1 micron to 0.9 microns. The gate trench mask 1600 can be removed after the gate trenches 1804 are defined.

The power transistor can have a gap resistance corresponding to the gap regions 352 and a channel resistance corresponding to the channel regions of transistor structures of the power transistor. The gap resistance can be in a range of 0.1 times to 10.0 times, 0.2 times to 5.0 times, or 0.5 times to 2.0 times the channel resistance. The gap resistance can be changed by adjusting the lengths and widths of the gap regions 352, and the channel resistance can be changed by adjusting the effective channel width of the power transistor.

If the previously described anneal was not performed before defining the gate trenches 1804, the anneal can be performed after defining the gate trenches 1804. The anneal can be performed before forming the gate dielectric layer 2314. When the anneal is performed after defining the gate trenches 1804, the graphite capping layer may fill or at least partially fill the gate trenches 1804.

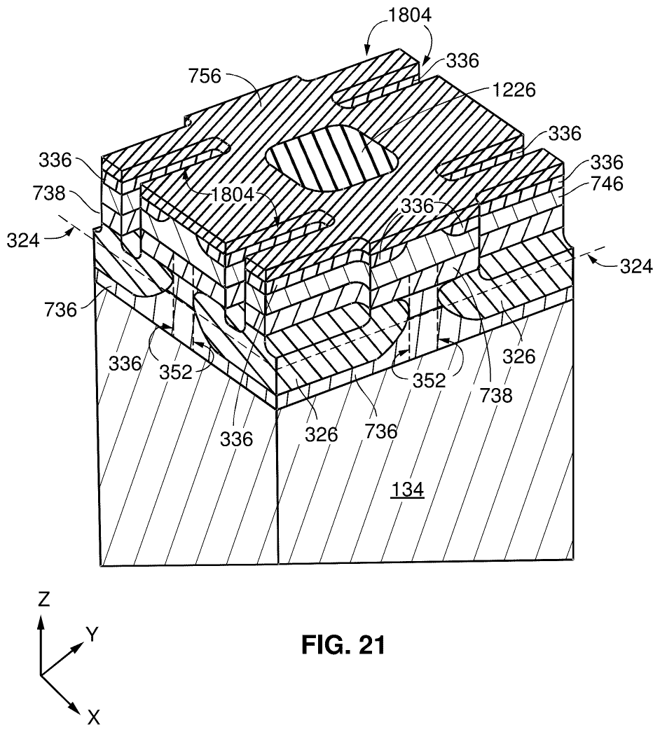

FIG. 21 includes a perspective view of a portion of the workpiece 100 at this point in the process. With respect to the upper surface, the view is centered about the body contact region 1226. Two different gap regions 352 are illustrated in FIG. 21. The shallow portion 756 of the source region overlaps the gap regions 352. The deep portion 336 of the source region does not overlap the gap regions 352.

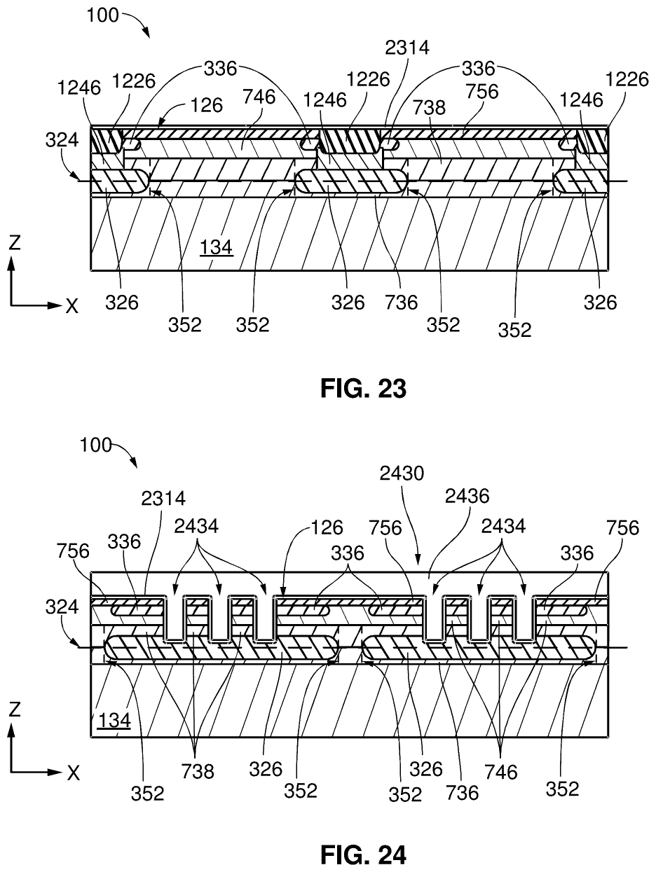

Referring briefly to FIGS. 23 to 26, a gate dielectric layer 2314 can be formed along exposed surfaces of the workpiece 100, including the sidewalls and bottoms of the gate trenches 1804 and over the shallow portion 756 of the source region and the body contact regions 1226 that are along the major surface 126. In an implementation, the gate dielectric layer 2314 is spaced apart from and does not physically contact the gap regions 352. The gate dielectric layer 2314 can include an oxide or an oxynitride. In an implementation, the gate dielectric layer 2314 can have a thickness in a range from 20 nm to 150 nm.

After formation of the gate dielectric layer 2314, a gate conductive layer can be deposited over the gate dielectric layer 2314. The gate conductive layer can include a single film or a plurality of films, where the single film or any of the films within the plurality of films can include a doped semiconductor layer, an elemental metal (a metal that is not part of an alloy and not part of a compound, such as W, Cu, Al, etc.), a metal alloy (for example, TiW, Al-1 wt % Cu, or the like), or a conductive metal compound (for example, a conductive metal silicide or a conductive metal nitride). The gate conductive layer can have a thickness sufficient to fill the gate trenches 1804. In a particular implementation, the gate conductive layer can be n-type doped polysilicon.

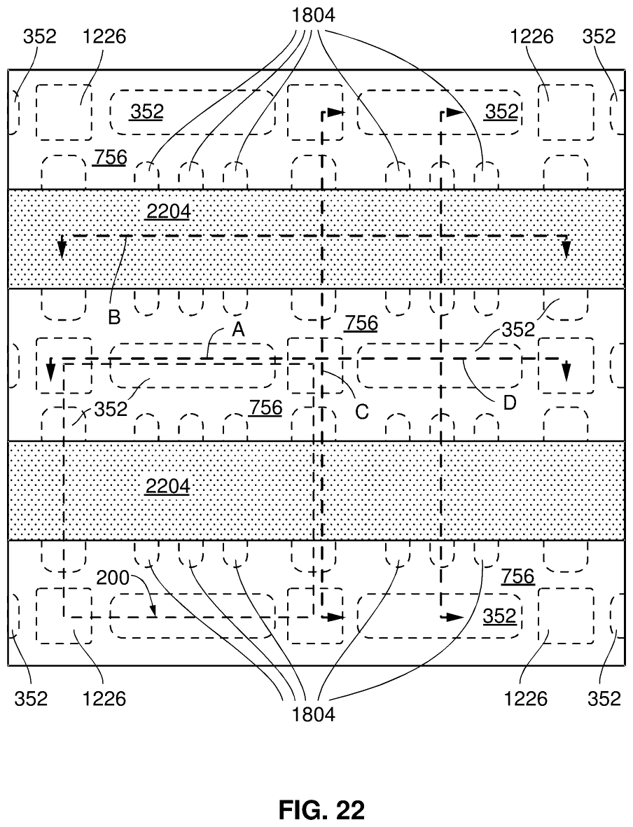

FIG. 22 includes a top view of a gate mask over the workpiece 100. The gate mask includes gate mask members 2204 that are used to define gate members. The gate mask members 2204 can be in the form of stripes that have lengths that are in the X-direction. The gate mask can have the same or a different composition as previously described with respect to the buried shield mask. In an implementation, the mask members 2204 can be made from an oxide layer similar to the relatively thicker oxide layer 376 previously described, and thus, the relatively thinner oxide layer 372, the polysilicon layer 374, or both may or may not be present. In another implementation, the gate mask members 2204 can be made of photoresist.

Some features are illustrated in FIG. 22 to assist in understanding the layout. All of the workpiece illustrated in FIG. 22 is covered by the gate conductive layer, portions of which are covered by the gate mask members 2204. The gate conductive layer overlaps the gap regions 352, the shallow portion 756 of the source region, the body contact regions 1226, and the gate trenches 1804. The shallow portion 756 of the source region and the body contact regions 1226 can lie at the major surface 126 (labelled in FIGS. 17 to 20). The gap regions 352 are farther into the workpiece 100 and spaced apart from the major surface 126. Some, but not all, gap regions 352, the body contact regions 1226, and the gate trenches 1804 are labelled in FIG. 22.

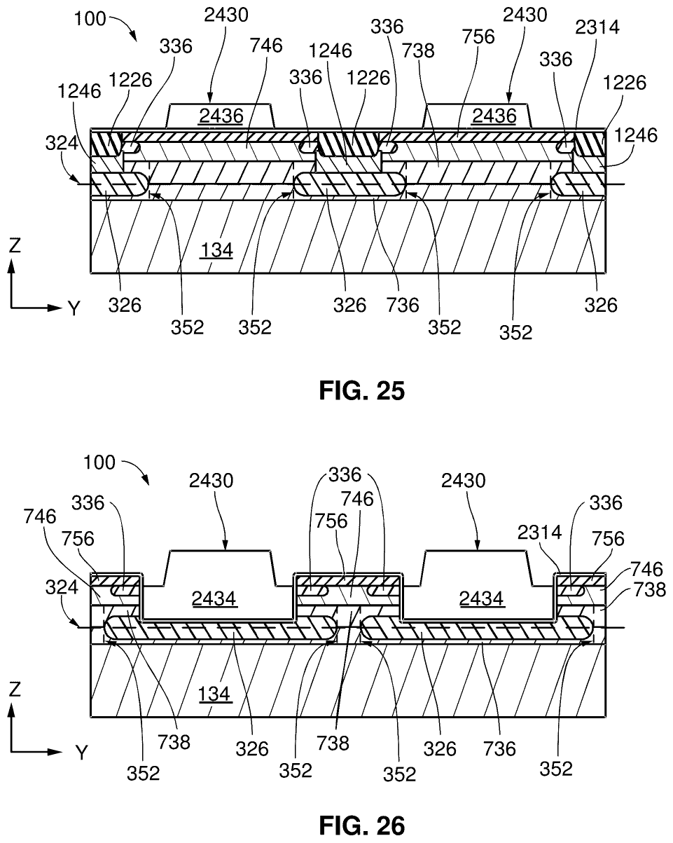

FIGS. 23 to 26 include cross-sectional views of the workpiece 100 after etching the gate conductive layer to form the gate members 2430 and removing the gate mask members 2204. FIG. 23 is along the sectioning line A in FIG. 22, FIG. 24 is along the sectioning line B in FIG. 22, FIG. 25 is along the sectioning line C in FIG. 22, and FIG. 26 is along the sectioning line D in FIG. 22.

An etch can be performed to remove portions of the gate conductive layer that overlie the gap regions 352, portions of the shallow portion 756 of the source region, and the body contact regions 1226 outside the gate trenches to form gate members 2430 that can include gate electrodes 2434 that extend into the gate trenches 1804 and intermediate portions 2436 outside of the gate trenches 1804. The etch can be performed as a timed etch or with endpoint detection and an overetch. Endpoint detection can occur when the gate dielectric layer 2314 is exposed. The overetch can be performed to recess portions of the gate electrodes 2434 within the gate trenches 1804 to reduce gate-to-source capacitance, C_{GS}. The elevation along the upper surfaces of the recessed portions of the gate electrodes are no lower than the lowermost points of the source region along their corresponding gate trenches 1804. When both the deep portion 336 and the shallow portion 756 of the source region are present adjacent to gate trenches 1804, there is more process margin for the recessing of the gate electrodes than in a case where the deep portion 336 of the source region was not present. Since the gate electrodes should at least partially overlap the source region for good control of the threshold voltage, the presence of the deep portion 336 of the source region can improve the threshold voltage control and manufacturability of the device. In another implementation, relatively higher C_{GS} may be acceptable, and the gate electrodes 2434 may not be recessed within the gate trenches 1804. As illustrated in FIGS. 23 to 26, the gate dielectric layer 2314 is located between the gate members 2430 and the major surface 126 and sidewalls and bottoms of the gate trenches 1804.

The gate mask members 2204 are removed after the gate conductive layer is etched to form the gate members 2430. If needed or desired, a silicide process can be performed to silicide exposed surfaces of the gate members 2430 when the gate members 2430 include doped polysilicon.

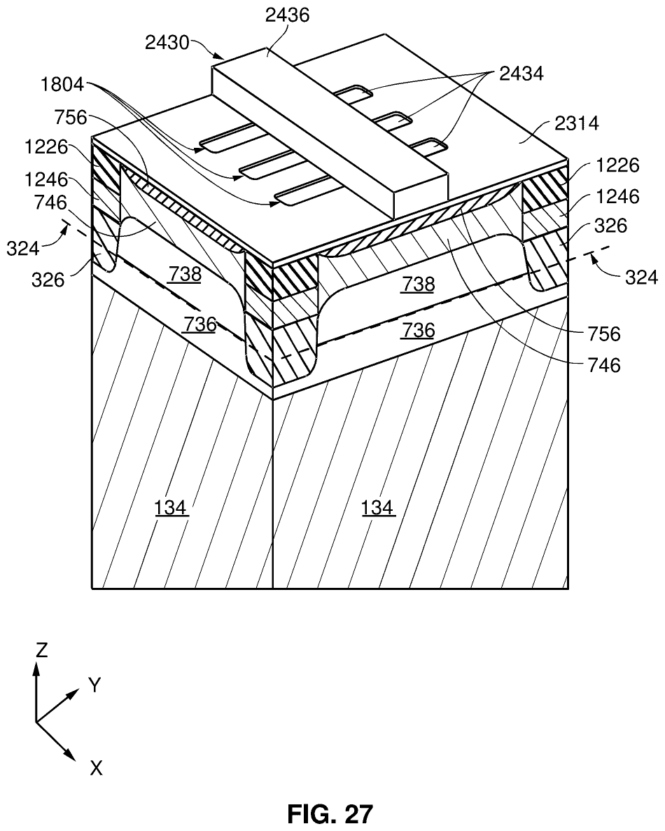

FIG. 27 includes a perspective view of a portion of the workpiece 100 at this point in the process. The view in FIG. 27 can correspond to the unit cell 200. The gate dielectric layer 2314 lies along the major surface 126 of the workpiece 100 and sidewalls of the gate trenches 1804. The gate member 2430 in FIG. 27 include gate electrodes 2434 within the gate trenches 1804 and intermediate portions 2436 outside of the gate trenches 1804. Parts of body contact regions 1226, the link regions 1246 and the buried shield 326 are in the corners. Two different gap regions 352 are illustrated along their lengths. The shallow portion 756 of the source region overlaps the gap regions 352. The deep portion 336 of the source region does not overlap the gap regions 352 and is not illustrated in FIG. 27.

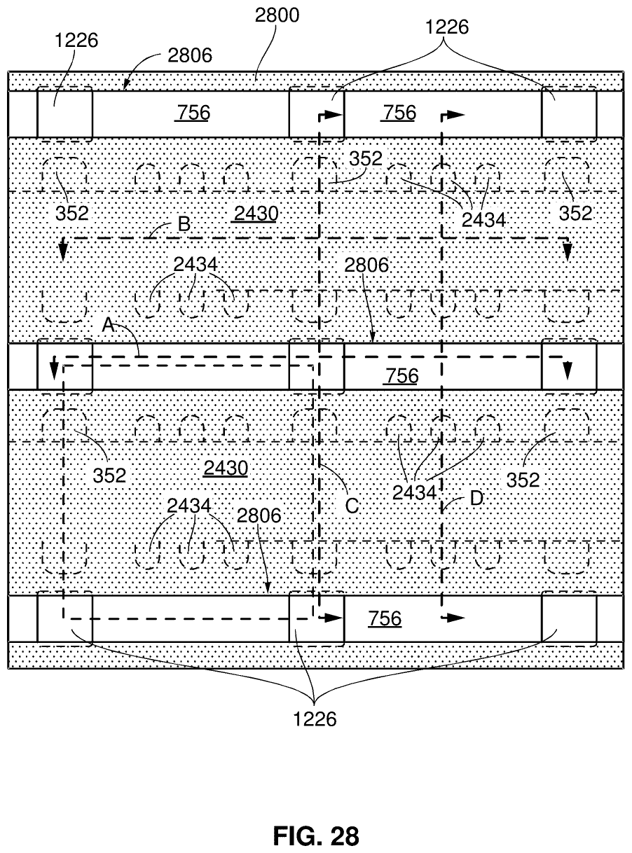

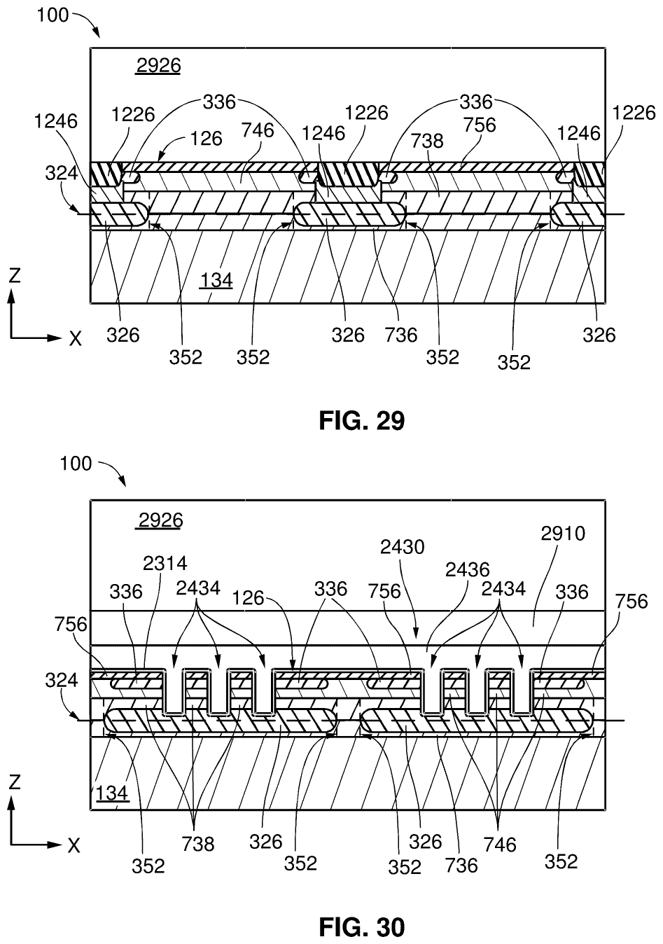

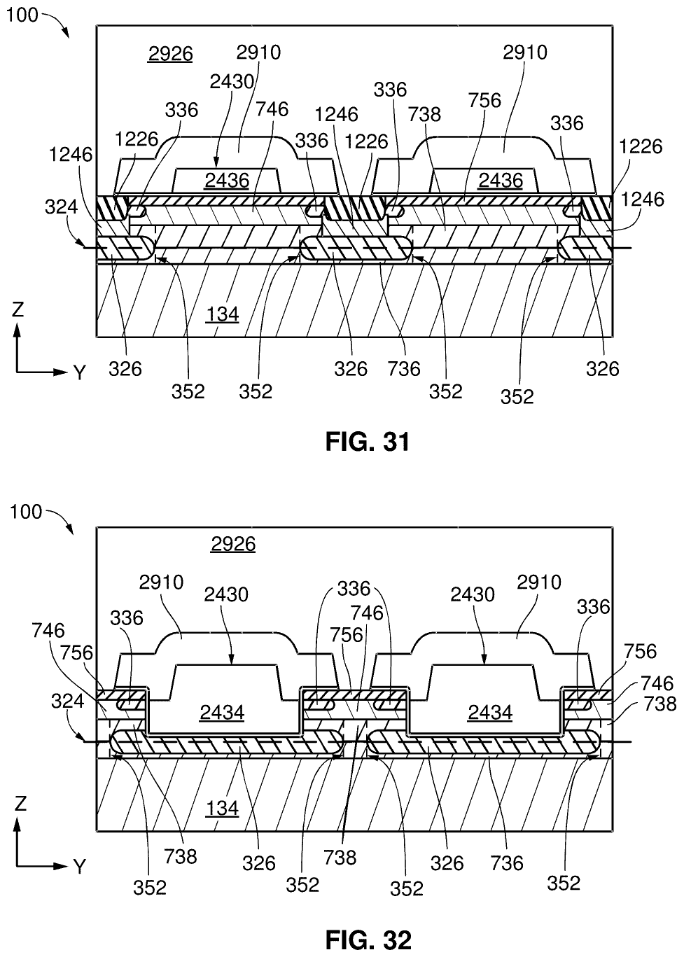

Referring to FIGS. 28 to 32, an interlevel dielectric (ILD) layer 2910 can be formed over the workpiece 100, and a contact mask 2800 can be formed over the ILD layer 2910 and include contact openings 2806. FIGS. 29 to 32 include cross-sectional views of the workpiece 100 after forming the source terminal 2926. FIG. 29 is along the sectioning line A in FIG. 28, FIG. 30 is along the sectioning line B in FIG. 28, FIG. 31 is along the sectioning line C in FIG. 28, and FIG. 32 is along the sectioning line D in FIG. 28.

The ILD layer 2910 can include a single film or a plurality of films. The single film or any one or more of the films within the plurality of films can include an oxide, a nitride, or an oxynitride. The single film or any one or more of the films within the plurality of films may or may not be doped with boron, phosphorus, or the like. The ILD layer 2910 can be deposited to a thickness in a range from 0.5 micron to 3.0 microns. A planarization process can be performed so that the uppermost surface of the ILD layer 2910 lies along a plane. The planarization process can be performed using chemical mechanical polishing or a resist etch-back process.

The contact mask 2800 defines the contact openings 2806 that expose portions of the ILD layer 2910. The contact mask 2800 can be made of photoresist. The contact openings 2806 overlap parts of the shallow portion 756 of the source region and body contact regions 1226. In FIG. 28, some, and not all, of the body contact regions 1226 and portions of the shallow portion 756 of the source region are labeled. The contact openings 2806 can be spaced apart from the gate members 2430. The contact mask 2800 can include other openings that expose portions (not illustrated in FIG. 28) of the gate members 2430, wherein such openings are located along the workpiece 100 at locations outside of the views as illustrated in FIGS. 28 to 32. The ILD layer 2910 is etched to expose parts of the shallow portion 756 of the source region, the body contact regions 1226, and the gate members 2430. The contact mask 2800 is removed after the etch is performed.

A conductive layer is deposited over the ILD layer 2910 and within contact openings extending through the ILD layer 2910 to contact the shallow portion 756 of the source region, the body contact regions 1226, and the gate members 2430. The conductive layer can include one or more films, wherein each film includes a conductive material. In an implementation, the conductive material can include a doped semiconductor material, an elemental metal (a metal that is not part of a compound or an alloy), a metal alloy, or a conductive metallic compound. A non-limiting example of a conductive material can be doped polysilicon (n-type or p-type), W, WN, Ti, Ta, TiW, Al-1 wt % Cu, Ni, Cu, Au, Pt, a conductive metal nitride (e.g., WN, TiN, TaN, etc.), a conductive metal silicide (NiSi, TiSi₂, CoSi₂, PtSi, etc.), or the like. In an implementation, the conductive layer can be deposited to a thickness in a range from 0.7 micron to 5.0 microns.

A photoresist mask is formed over the conductive layer, and the conductive layer is patterned to form a source terminal 2926 in FIGS. 29 to 32 and a gate terminal (not illustrated). The source terminal 2926 physically contacts the shallow portion 756 of the source region and the body contact regions 1226. In an implementation, ohmic contacts are formed between the source terminal 2926 and the shallow portion 756 of the source region and the body contact regions 1226. The gate terminal can physically contact the gate members 2430.

If needed or desired, a passivation layer (not illustrated) can be formed over the ILD layer 2910, the source terminal 2926, and the gate terminal. The passivation layer can include one or more films of a insulating material. In a particular implementation, the passivation layer includes polyimide that is coated and patterned to expose portions of the source terminal 2926 and the gate terminal. The reverse side of the workpiece may be provided with a metal layer that is a drain terminal and physically contacts the semiconductor base material 132.

FIG. 33 includes a cross-sectional view of portions of unit cells adjacent to one of the gap regions 352 to illustrate the majority carrier flow within the transistor structures. Portions of the workpiece above the major surface 126 are removed to improve understanding of features of the power transistor. Body contact regions 1226 and link regions 1246 are present but not seen in FIG. 33. The majority carrier flow is illustrated with the arrows. Majority carriers are electrons for an n-channel transistor and holes for a p-channel transistor.

In a finished device and when the power transistor is in an on-state, majority carriers flow along paths from the shallow portion 756 and the deep portion 336 of the source region, through channel regions that are portions of the body region 746 that are adjacent to the sidewalls of the gate trenches 1804, into the carrier accumulation region 738, into the carrier distribution layer 736 via the gap region 352, through the semiconductor layer 134, through the semiconductor base material 132 (not illustrated in FIG. 33), and into a drain terminal (not illustrated) for the power transistor.

The majority carriers flow substantially vertically (in the Z-direction) through the channel region and are illustrated in FIG. 33 with arrows extending through the body region 746 and into the carrier accumulation region 738. After entering the carrier accumulation region 738, the majority carriers flow substantially laterally (in the X-direction) between the body region 746 and the buried shield 326 and are illustrated in FIG. 33 with arrows within the carrier accumulation region 738. Although FIG. 33 includes arrows illustrated in the X-direction passing through the center of carrier accumulation region 738, the majority carriers are not restricted to flow only along the center of the carrier accumulation region 738. At least some of the majority carriers can flow through the carrier accumulation region 738 at locations other than in the center of the carrier accumulation region 738.

The majority carriers enter the gap region then flow substantially vertically (in the Z-direction) through gap region 352 and enter the carrier distribution layer 736. Although FIG. 33 includes a single arrow illustrated in the Z-direction passing through the center of gap region 352, the majority carriers are not restricted to flow only along the center of the gap region 352. At least some of the majority carriers can flow through the gap region 352 at locations other than in the center of the gap region 352.

The carrier distribution layer 736 helps to distribute more uniformly the majority carriers into semiconductor layer 134 as compared to transistor structures where the carrier distribution layer 736 would have been restricted only to the gap region 352 or where the carrier distribution layer 736 is replaced by the semiconductor layer 134 (the semiconductor layer 134 would have extended into the gap region 352 and physically contacted the carrier accumulation region 738).

After entering the carrier distribution layer 736, at least some of the majority carriers can flow substantially laterally (in the X-direction) under the buried shield 326 and are illustrated in FIG. 33 with a double-headed arrow extending within the carrier distribution layer 736. The majority carriers can then flow from the carrier distribution layer 736 into the semiconductor layer 134 and are illustrated with the vertical arrows (in the Z-direction) extending from the double-headed arrow within the carrier distribution layer 736 to the semiconductor layer 134. Although FIG. 33 includes the double-headed arrow illustrated in the X-direction passing through the center of carrier distribution layer 736, the majority carriers are not restricted to flow in the X-direction only along the center of the carrier distribution layer 736. At least some of the majority carriers can flow through the carrier distribution layer 736 at locations other than in the center of the carrier distribution layer 736. The majority carriers can flow in a substantially vertical direction within the semiconductor layer 134 and the semiconductor base material 132 (not illustrated in FIG. 33). Referring to FIG. 33, the majority carrier flow from the carrier distribution layer 736 into the semiconductor layer 134 is illustrated with relatively thinner arrows in the Z-direction.

In FIG. 33, the parts of the deep portion 336 of the source region do not overlap the gap region 352 and are laterally spaced apart from the gap region 352. The shallow portion 756 of the source region extends across all of the width of the gap region 352 as illustrated in FIG. 33. The body region 746 is locally thicker over the gap region 352 as compared to the channel regions of the transistor structures at the gate trenches 1804. The combination of shallow and deep portions 756 and 336 of the source region as illustrated in FIG. 33 allows for acceptable low source contact resistance and a relatively higher drain-to-source punch through voltage because the body region 746 is thicker over the gap region 352. If the deep portion 336 of the source region would have extended across all of the gap region 352, the power transistor would have relatively lower drain-to-source punch through voltage.

Many of the implementations have benefits over conventional designs of power transistors. While benefits are described with respect to particular implementations, not all benefits need to be present in all implementation, and all implementations may not enjoy all the benefits as described herein.

As previously addressed, the combination of the shallow and deep portions 756 and 336 can allow for good (low) source resistance and controlling the channel length of the transistor structures of the power transistor by controlling the depth of the deep portion 336 of the source region while maintaining an acceptable BV_{DS} for the power transistor that may be achieved by spacing the deep portion 336 of the source region so that it does not overlap any one or more of the gap regions 352.

Gap regions 352 can be organized such that lengths of the gap regions 352 are oriented in different directions. Referring to FIGS. 2 to 6, the gap regions 352 correspond to the mask members 206. In the implementation as illustrated, the lengths of some of the gap regions 352 are substantially orthogonal to the lengths of other gap regions 352. The design of the gap regions 352 can help to reduce R_{SP} by reducing gap resistance corresponding to the gap regions 352. The gap regions 352 can be designed such that the gap resistance is closer to the channel resistance corresponding to the channel regions for transistor structures of a power transistor, as compared to all gap regions 352 having lengths oriented along the same direction (all in the X-direction or all in the Y-direction). As the amount of area occupied by the gap regions 352 increases, gap resistance decreases. However, the channel resistance may become substantially more predominant as compared to the gap resistance. Further decreasing the gap resistance may not significantly affect R_{SP}. As the area occupied by the gap regions 352 increases, the number of gate trenches may decrease and reduce effective channel width of power transistor, where the effective channel width is the sum of the channel widths of the transistor structures that make up the power transistor. After reading this specification, skilled artisans will be able to run simulations to determine the design of the gap regions that achieve transistor characteristics that meet the needs or desires for a particular application.

Many different aspects and implementations are possible. Some of those aspects and implementations are described below. After reading this specification, skilled artisans will appreciate that those aspects and implementations are only illustrative and do not limit the scope of the inventive concepts. Implementations may be in accordance with any one or more of the implementations as listed below.

Implementation 1. An electronic device can include a substrate defining a gate trench that extends to a gate trench depth from a major surface of the substrate; a source region having a first conductivity type; a body region having a second conductivity type opposite the first conductivity type, wherein the body region underlaps the source region; a buried shield having the second conductivity type, wherein the buried shield underlaps at least a portion of the body region and the gate trench; and a gap region having the first conductivity type, wherein the gap region is defined at least in part by the buried shield and has a gap region width that is a width of the gap region. The source region can include a shallow portion and a deep portion. A centerline can pass through a center of the width of the gap region, wherein the centerline is perpendicular to the major surface. The centerline can further pass through the shallow portion of the source region and does not pass through the deep portion of the source region.

Implementation 2. The electronic device of Implementation 1, wherein the shallow portion and the deep portion of the source region lie along a sidewall of the gate trench, and a portion of the body region underlaps the shallow portion of the source region and does not underlap the deep portion of the source region.

Implementation 3. The electronic device of Implementation 1 further includes a body contact region having the second conductivity type. The body contact region physically contacts the shallow portion of the source region and the deep portion of the source region. At a location spaced apart from the body contact region, the shallow portion does not overlap the deep portion.

Implementation 4. The electronic device of Implementation 3 further includes a link region having the second conductivity type, wherein the body contact region and the buried shield are electrically connected to each other via the link region.

Implementation 5. The electronic device of Implementation 4, wherein the body contact region overlaps the link region, and the link region overlaps the buried shield.

Implementation 6. The electronic device of Implementation 2 further includes a gate member that includes a gate electrode extending into the gate trench.

Implementation 7. The electronic device of Implementation 1 further includes a carrier accumulation region having the first conductivity type, wherein the body region overlaps the carrier accumulation region, and the carrier accumulation region overlaps the buried shield.

Implementation 8. The electronic device of Implementation 7, wherein the carrier accumulation region extends across all of the width of the gap region.

Implementation 9. The electronic device of Implementation 7 further includes a carrier distribution layer having the first conductivity type, wherein the carrier distribution layer extends into the gap region, and the buried shield overlaps a portion of the carrier distribution layer.

Implementation 10. An electronic device can include a substrate defining a gate trench that extends to a gate trench depth from a major surface of the substrate, wherein the substrate includes a semiconductor layer having a first conductivity type. The electronic device can further include a buried shield having a second conductivity type, wherein the buried shield underlaps at least a portion of the gate trench.

The electronic device can still further include a first gap region and a second gap region. The first gap region has the first conductivity type, the first gap region is defined at least in part by the buried shield, and the first gap region has a length and a width, wherein the length is greater than the width, and the length of the first gap region is along a first line. The second gap region has the first conductivity type, the second gap region is defined at least in part by the buried shield, the second gap region has a length and a width, wherein the length is greater than the width, and the length of the second gap region is along a second line that intersects the first line.

Implementation 11. The electronic device of Implementation 10, wherein the first line intersects the second line at an angle that is 90°+/−5°.

Implementation 12. The electronic device of Implementation 10 further includes a body region having a second conductivity type opposite the first conductivity type; and a carrier accumulation region having the first conductivity type and located between the body region and the buried shield.

Implementation 13. The electronic device of Implementation 12, wherein the electronic device includes a power transistor, the power transistor includes a plurality of gap regions, including the first gap region and the second gap region, the power transistor includes a plurality of transistor structures having a plurality of channel regions, the power transistor has a gap resistance corresponding to the plurality of gap regions, and a channel resistance corresponding to the plurality of channel regions, and the gap resistance is in a range of 0.1 to 10.0 times the channel resistance.

Implementation 14. The electronic device of Implementation 12 further includes a carrier distribution layer having the first conductivity type. The buried shield overlaps a portion of the carrier distribution layer, and the first gap region and the second gap region include portions of the carrier accumulation region and the carrier distribution layer between portions of the buried shield.

Implementation 15. The electronic device of Implementation 10 further includes a third gap region and a fourth gap region. The third gap region has the first conductivity type, the third gap region is defined at least in part by the buried shield, the third gap region has a length and a width, wherein the length is greater than the width, and the length of the third gap region is along a third line that extends in a same first direction as the first line. The fourth gap region has the first conductivity type, the fourth gap region is defined at least in part by the buried shield, the fourth gap region has a length and a width, wherein the length is greater than the width, and the length of the fourth gap region is along a fourth line that extends in a same second direction as the second line. A unit cell of a power transistor includes at least parts of the first gap region, the second gap region, the third gap region, and the fourth gap region.

Implementation 16. An electronic device can include a substrate defining a gate trench that extends to a gate trench depth from a major surface of the substrate; a source region having a first conductivity type; a body region having a second conductivity type opposite the first conductivity type, wherein the body region underlaps the source region; a buried shield having the second conductivity type, wherein the buried shield underlaps at least a portion of the body region and the gate trench; and a gap region having the first conductivity type, wherein the gap region is defined at least in part by the buried shield. The source region can include a shallow portion and a first deep portion, the shallow portion of the source region and the first deep portion of the source region lie along a sidewall of the gate trench, and a portion of the body region underlaps the shallow portion of the source region and does not underlap the first deep portion of the source region.

Implementation 17. The electronic device of Implementation 16 further includes a body contact region having the second conductivity type. The source region further includes a second deep portion, and the body contact region physically contacts the shallow portion of the source region and the second deep portion of the source region.

Implementation 18. The electronic device of Implementation 16, wherein the source region further includes other deep portions, and none of the first deep portion and the other deep portions of the source region overlaps the gap region.

Implementation 19. The electronic device of Implementation 16 further includes a body contact region having the second conductivity type opposite the first conductivity type; and a link region having the second conductivity type, wherein the body contact region and the buried shield are electrically connected to each other via the link region.

Implementation 20. The electronic device of Implementation 16 further includes a carrier accumulation region having the first conductivity type, wherein the body region overlaps the carrier accumulation region, and the carrier accumulation region overlaps the buried shield. The electronic device further includes a carrier distribution layer having the first conductivity type, wherein the carrier distribution layer extends into the gap region, and the buried shield overlaps a portion of the carrier distribution layer.

Implementation 21. The electronic device of Implementation 16 further includes a gate member that includes a gate electrode extending into the gate trench, wherein a channel length of the transistor structure corresponds to a thickness of the body region along the sidewall of the gate trench.

Implementation 22. An electronic device can include a substrate defining a gate trench that extends to a gate trench depth from a major surface of the substrate; a source region having a first conductivity type; a body region having a second conductivity type opposite the first conductivity type, wherein the body region underlaps the source region; a first body contact region having the second conductivity type, wherein the first body contact region is electrically coupled to the body region; a buried shield having the second conductivity type, wherein the buried shield underlaps at least a portion of the body region and the gate trench; and a gap region having the first conductivity type, wherein the gap region is defined at least in part by the buried shield. The source region includes a shallow portion and a deep portion, the first body contact region physically contacts the shallow portion of the source region and the deep portion of the source region, and at a location spaced apart from the first body contact region, the shallow portion does not overlap the deep portion.

Implementation 23. The electronic device of Implementation 22 further includes a gate member that includes a gate electrode extending into the gate trench.

Implementation 24. The electronic device of Implementation 23 further includes other body contact regions having the second conductivity type and spaced apart from one another, wherein none of the gate member overlaps the first body contact region and the other body contact regions.

Implementation 25. The electronic device of Implementation 23, wherein a channel length of the transistor structure corresponds to a thickness of the body region along a sidewall of the gate trench.

Implementation 26. The electronic device of Implementation 22 further includes a carrier accumulation region having the first conductivity type, wherein the body region overlaps the carrier accumulation region, and the carrier accumulation region overlaps the buried shield; and a carrier distribution layer having the first conductivity type, wherein the carrier distribution layer extends into the gap region, and the buried shield overlaps a portion of the carrier distribution layer.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations may also be provided in combination in a single implementation, and conversely, various features that are, for brevity, described in the context of a single implementation, may also be provided separately or in any subcombination. Further, reference to values stated in ranges includes each and every value within that range. Many other implementations may be apparent to skilled artisans only after reading this specification. Other implementations may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device, comprising:
a substrate defining a gate trench that extends to a gate trench depth from a major surface of the substrate;
a source region having a first conductivity type;
a body region having a second conductivity type opposite the first conductivity type, wherein the body region underlaps the source region;
a buried shield having the second conductivity type, wherein the buried shield underlaps at least a portion of the body region and the gate trench; and
a gap region having the first conductivity type, wherein the gap region is defined at least in part by the buried shield and has a gap region width that is a width of the gap region,
wherein:
the source region includes a shallow portion and a deep portion,
a centerline passes through a center of the width of the gap region, wherein the centerline is perpendicular to the major surface, and
the centerline further passes through the shallow portion of the source region and does not pass through the deep portion of the source region.

2. The electronic device of claim 1, wherein:
the shallow portion and the deep portion of the source region lie along a sidewall of the gate trench, and a portion of the body region underlaps the shallow portion of the source region and does not underlap the deep portion of the source region.

3. The electronic device of claim 1, further comprising:
a body contact region having the second conductivity type, wherein:
the body contact region physically contacts the shallow portion of the source region and the deep portion of the source region, and
at a location spaced apart from the body contact region, the shallow portion does not overlap the deep portion.

4. The electronic device of claim 3, further comprising:
a link region having the second conductivity type, wherein the body contact region and the buried shield are electrically connected to each other via the link region.

5. The electronic device of claim 4, wherein the body contact region overlaps the link region, and the link region overlaps the buried shield.

6. The electronic device of claim 2, further comprising:
a gate member that includes a gate electrode extending into the gate trench.

7. The electronic device of claim 1, further comprising:
a carrier accumulation region having the first conductivity type, wherein the body region overlaps the carrier accumulation region, and the carrier accumulation region overlaps the buried shield.

8. The electronic device of claim 7, wherein the carrier accumulation region extends across all of the width of the gap region.

9. The electronic device of claim 7, further comprising:
a carrier distribution layer having the first conductivity type,
wherein the carrier distribution layer extends into the gap region, and the buried shield overlaps a portion of the carrier distribution layer.

10. An electronic device, comprising:
a substrate defining a gate trench that extends to a gate trench depth from a major surface of the substrate, wherein the substrate includes a semiconductor layer having a first conductivity type;
a buried shield having a second conductivity type opposite the first conductivity type, wherein the buried shield underlaps at least a portion of the gate trench;
a first gap region having the first conductivity type, wherein:
the first gap region is defined at least in part by the buried shield,
the first gap region has a length and a width, wherein the length is greater than the width, and
the length of the first gap region is along a first line; and
a second gap region having the first conductivity type, wherein:
the second gap region is defined at least in part by the buried shield,
the second gap region has a length and a width, wherein the length is greater than the width, and
the length of the second gap region is along a second line that intersects the first line.

11. The electronic device of claim 10, wherein the first line intersects the second line at an angle that is 90°+/−5°.

12. The electronic device of claim 10, further comprising:
a body region having the second conductivity type; and
a carrier accumulation region having the first conductivity type and located between the body region and the buried shield.

13. The electronic device of claim 12, wherein:
the electronic device includes a power transistor,
the power transistor includes a plurality of gap regions, including the first gap region and the second gap region,
the power transistor includes a plurality of transistor structures having a plurality of channel regions,
the power transistor has a gap resistance corresponding to the plurality of gap regions, and a channel resistance corresponding to the plurality of channel regions, and
the gap resistance is in a range of 0.1 to 10.0 times the channel resistance.

14. The electronic device of claim 12, further comprising:
a carrier distribution layer having the first conductivity type,
wherein:
the buried shield overlaps a portion of the carrier distribution layer, and
the first gap region and the second gap region include portions of the carrier accumulation region and the carrier distribution layer between portions of the buried shield.

15. The electronic device of claim 10, further comprising:
a third gap region having the first conductivity type, wherein:
the third gap region is defined at least in part by the buried shield,
the third gap region has a length and a width, wherein the length is greater than the width, and
the length of the third gap region is along a third line that extends in a same first direction as the first line; and
a fourth gap region having the first conductivity type, wherein:
the fourth gap region is defined at least in part by the buried shield,
the fourth gap region has a length and a width, wherein the length is greater than the width, and
the length of the fourth gap region is along a fourth line that extends in a same second direction as the second line,
wherein a unit cell of a power transistor includes at least parts of the first gap region, the second gap region, the third gap region, and the fourth gap region.

16. An electronic device, comprising:
a substrate defining a gate trench that extends to a gate trench depth from a major surface of the substrate;
a source region having a first conductivity type;
a body region having a second conductivity type opposite the first conductivity type, wherein the body region underlaps the source region;
a buried shield having the second conductivity type, wherein the buried shield underlaps at least a portion of the body region and the gate trench; and
a gap region having the first conductivity type, wherein the gap region is defined at least in part by the buried shield,
wherein:
the source region includes a shallow portion and a first deep portion,
the shallow portion of the source region and the first deep portion of the source region lie along a sidewall of the gate trench, and
a portion of the body region underlaps the shallow portion of the source region and does not underlap the first deep portion of the source region.

17. The electronic device of claim 16, further comprising:
a body contact region having the second conductivity type,
wherein:
the source region further includes a second deep portion, and
the body contact region physically contacts the shallow portion of the source region and the second deep portion of the source region.

18. The electronic device of claim 16, wherein:
the source region further includes other deep portions, and
none of the first deep portion and the other deep portions of the source region overlaps the gap region.

19. The electronic device of claim 16, further comprising:
a body contact region having the second conductivity type opposite the first conductivity type; and
a link region having the second conductivity type, wherein the body contact region and the buried shield are electrically connected to each other via the link region.

20. The electronic device of claim 16, further comprising:
a carrier accumulation region having the first conductivity type, wherein the body region overlaps the carrier accumulation region, and the carrier accumulation region overlaps the buried shield; and
a carrier distribution layer having the first conductivity type, wherein the carrier distribution layer extends into the gap region, and the buried shield overlaps a portion of the carrier distribution layer.
